(19) United States
(12) Patent Application Publication
(10) Pub. No.: US 2026/0157037 A1
(43) Pub. Date: Jun. 4, 2026

(54) DISPLAY DEVICE AND ELECTRONIC DEVICE INCLUDING THE SAME

(71) Applicant: Samsung Display Co., Ltd., Yongin-si (KR)

(72) Inventors: YONGHEE LEE, Yongin-si (KR); KYUNG-BAE KIM, Yongin-si (KR); DONGWOO KIM, Yongin-si (KR); YEONKYUNG KIM, Yongin-si (KR)

(21) Appl. No.: 19/261,978

(22) Filed: Jul. 7, 2025

(30) Foreign Application Priority Data
Nov. 29, 2024 (KR) 10-2024-0175342

(51) Int. Cl. H10K 59/121; H10K 59/35

(52) U.S. Cl. CPC H10K 59/1213; H10K 59/353

(57) ABSTRACT

A display device includes first, second, and third sub-pixels, wherein the first sub-pixel includes a first driving transistor including a first well area, and a first gate electrode thereabove, and a first switching transistor including a second well area, and a second gate electrode thereabove, the second sub-pixel includes a second driving transistor including a third well area, and a third gate electrode thereabove, and a second switching transistor including a fourth well area, and a fourth gate electrode thereabove and connected to the second gate electrode, and the third sub-pixel includes a third driving transistor including a fifth well area, and a fifth gate electrode thereabove, and a third switching transistor including a sixth well area, and a sixth gate electrode thereabove and connected to the second gate electrode.

### CROSS-REFERENCE TO RELATED APPLICATION(S)

This application claims priority to, and the benefit of, Korean Patent Application No. 10-2024-0175342 filed on Nov. 29, 2024, in the Korean Intellectual Property Office (KIPO), the entire disclosure of which is incorporated by reference herein.

### BACKGROUND

### 1. Field

Embodiments relate to a display device that provides visual information and an electronic device including the same.

### 2. Description of the Related Art

As information technology develops, importance of a display device, which is a connection medium between a user and information has been highlighted. Recently, a display device that provides virtual reality (VR) or augmented reality (AR) has been highlighted. In this case, the display device suitably uses a small area and a high PPI (pixels per inch). In this case, because a pitch occupied by a pixel circuit becomes narrow, there may be restrictions on the number of transistors constituting the pixel circuit, the arrangement of the transistors, or the like.

### SUMMARY

Embodiments provide a display device that implements high resolution.

Embodiments provide an electronic device including the display device.

A display device according to one or more embodiments of the present disclosure includes pixels including a first sub-pixel, a second sub-pixel, and a third sub-pixel adjacent to each other, wherein the first sub-pixel includes a first driving transistor including a first well area, and a first gate electrode above the first well area, and a first switching transistor including a second well area, and a second gate electrode above the second well area, the second sub-pixel includes a second driving transistor including a third well area, and a third gate electrode above the third well area, and a second switching transistor including a fourth well area, and a fourth gate electrode above the fourth well area and connected to the second gate electrode, and the third sub-pixel includes a third driving transistor including a fifth well area, and a fifth gate electrode above the fifth well area, and a third switching transistor including a sixth well area, and a sixth gate electrode above the sixth well area and connected to the second gate electrode.

The second gate electrode, the fourth gate electrode, and the sixth gate electrode may be integral.

Sizes of the first driving transistor, the second driving transistor, and the third driving transistor may be larger than sizes of the first switching transistor, the second switching transistor, and the third switching transistor.

The first sub-pixel may define a first sub-pixel area for emitting first light, wherein the second sub-pixel defines a second sub-pixel area for emitting second light, and wherein the third sub-pixel defines a third sub-pixel area for emitting third light.

At least a portion of the first driving transistor and the first switching transistor may be arranged in the second sub-pixel area or the third sub-pixel area, wherein at least a portion of the second driving transistor and the second switching transistor is arranged in the first sub-pixel area or the third sub-pixel area, and wherein at least a portion of the third driving transistor and the third switching transistor is arranged in the first sub-pixel area or the second sub-pixel area.

The first gate electrode, the third gate electrode, and the fifth gate electrode may be spaced apart from each other.

The first gate electrode, the third gate electrode, and the fifth gate electrode may be integral.

The first well area and the second well area may be integral, wherein the third well area and the fourth well area are integral, and wherein the fifth well area and the sixth well area are integral.

The first well area may include a first source area and a first drain area, wherein the second well area includes a second source area and a second drain area, and wherein the first drain area is the second source area.

Adjacent ones of the pixels may be mirror-symmetrical.

The first sub-pixel may further include a fourth switching transistor including a seventh well area, and a seventh gate electrode above the seventh well area, wherein the second sub-pixel further includes a fifth switching transistor including an eighth well area, and an eighth gate electrode above the eighth well area, and wherein the third sub-pixel further includes a sixth switching transistor including a ninth well area, and a ninth gate electrode above the ninth well area.

The seventh gate electrode, the eighth gate electrode, and the ninth gate electrode may be spaced apart from each other.

The first well area and the first gate electrode may at least partially overlap in plan view, wherein the second well area and the second gate electrode at least partially overlap in plan view, wherein the third well area and the third gate electrode at least partially overlap in plan view, wherein the fourth well area and the fourth gate electrode at least partially overlap in plan view, wherein the fifth well area and the fifth gate electrode at least partially overlap in plan view, and wherein the sixth well area and the sixth gate electrode at least partially overlap in plan view.

The first light, the second light, and the third light may be respectively of different wavelength bands.

The first light may be light of a red wavelength band, wherein the second light is light of a green wavelength band, and wherein the third light is light of a blue wavelength band.

An electronic device according to one or more embodiments of the present disclosure includes a display device, and a processor for controlling the display device, wherein the display device includes pixels including a first sub-pixel, a second sub-pixel, and a third sub-pixel adjacent to each other, wherein the first sub-pixel includes a first driving transistor including a first well area, and a first gate electrode above the first well area, and a first switching transistor including a second well area, and a second gate electrode above the second well area, wherein the second sub-pixel includes a second driving transistor including a third well area, and a third gate electrode above the third well area, and a second switching transistor including a fourth well area, and a fourth gate electrode above the fourth well area and connected to the second gate electrode, and wherein the third sub-pixel includes a third driving transistor including a fifth well area, and a fifth gate electrode above the fifth well area, and a third switching transistor including a sixth well area, and a sixth gate electrode above the sixth well area and connected to the second gate electrode.

The second gate electrode, the fourth gate electrode, and the sixth gate electrode may be integral.

The first sub-pixel may define a first sub-pixel area for emitting first light, wherein the second sub-pixel defines a second sub-pixel area for emitting second light, wherein the third sub-pixel defines a third sub-pixel area for emitting third light, wherein at least a portion of the first driving transistor and the first switching transistor is arranged in the second sub-pixel area or the third sub-pixel area, wherein at least a portion of the second driving transistor and the second switching transistor is arranged in the first sub-pixel area or the third sub-pixel area, and wherein at least a portion of the third driving transistor and the third switching transistor is arranged in the first sub-pixel area or the second sub-pixel area.

The first gate electrode, the third gate electrode, and the fifth gate electrode may be integral.

The first well area and the second well area may be integral, wherein the third well area and the fourth well area are integral, and wherein the fifth well area and the sixth well area are integral.

In a display device according to embodiments of the present disclosure, the display device may include pixels each including a plurality of sub-pixels. At least one of transistors included in each of the sub-pixels may be arranged together while sharing a gate electrode or a well area. Accordingly, because a space within a pixel area may be sufficiently secured, a plurality of transistors may be arranged in the pixel area, and a size of a driving transistor may be sufficiently secured. Accordingly, the display device may be implemented with high resolution, and display quality of the display device may be improved.

### BRIEF DESCRIPTION OF THE DRAWINGS

FIG. 1 is a plan view illustrating a display device according to one or more embodiments of the present disclosure.

FIG. 2 is a block diagram illustrating the display device of FIG. 1.

FIG. 3 is a cross-sectional view illustrating an example of a display panel included in the display device of FIG. 1.

FIG. 4 is a circuit diagram illustrating an example of a pixel included in the display device of FIG. 1.

FIG. 5 is a plan view illustrating an example of a pixel included in the display device of FIG. 1.

FIG. 6 is a plan view illustrating a display device according to one or more embodiments of the present disclosure.

FIG. 7 is a plan view illustrating the display device of FIG. 6.

FIG. 8 is a block diagram illustrating an electronic device according to one or more embodiments of the present disclosure.

FIG. 9 is a diagram illustrating an example in which the electronic device of FIG. 8 is implemented as a VR device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

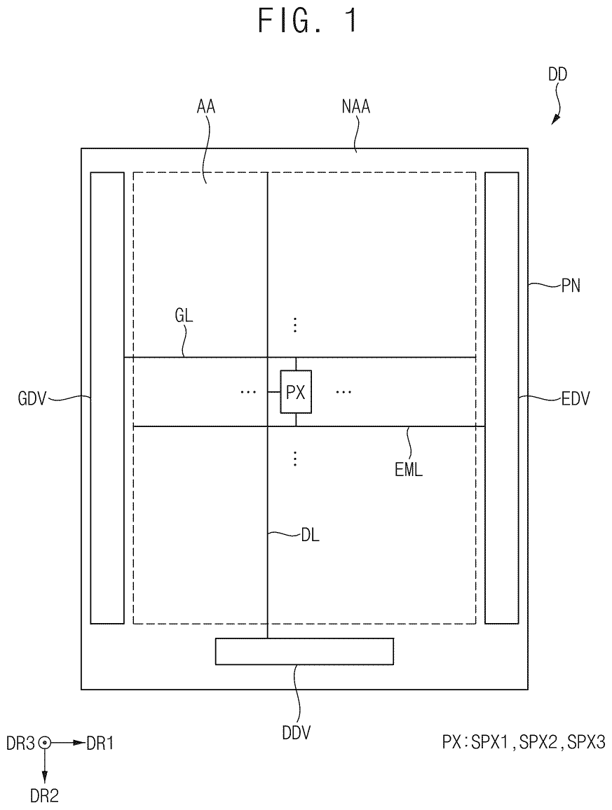

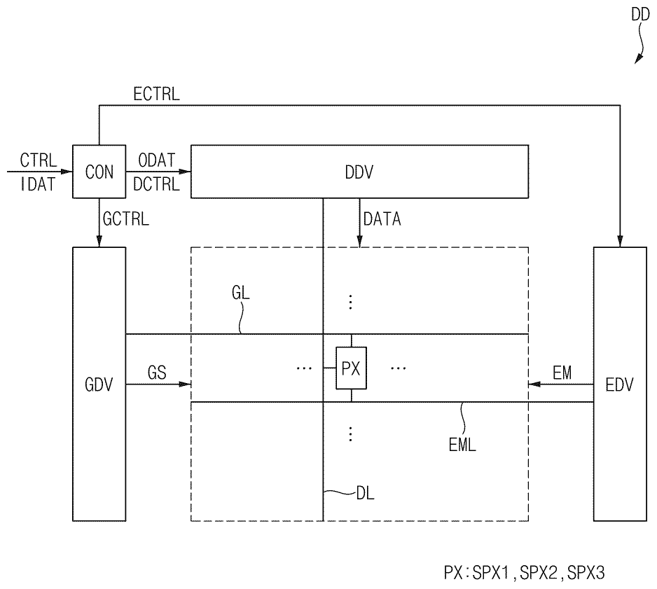

FIG. 1 is a plan view illustrating a display device according to one or more embodiments of the present disclosure. FIG. 2 is a block diagram illustrating the display device of FIG. 1.

Referring to FIGS. 1 and 2, a display device DD may include a display panel PN and a driver for driving the display panel PN. The display panel PN may include a display area AA and a non-display area NAA.

The display area AA may be an area that displays an image. A plurality of pixels PX may be arranged in the display area AA. For example, the pixels PX may be repeatedly arranged in a first direction DR1, and in a second direction DR2 crossing the first direction DR1. Each of the pixels PX may emit light, and accordingly, the display area AA may display an image. For example, the display area AA may display an image in a third direction DR3 crossing each of the first and second directions DR1 and DR2.

Each of the pixels PX may include a plurality of sub-pixels. Each of the pixels PX may include a first sub-pixel SPX1, a second sub-pixel SPX2, and a third sub-pixel SPX3. Each of the first, second, and third sub-pixels SPX1, SPX2, and SPX3 may emit light. The first, second, and third sub-pixels SPX1, SPX2, and SPX3 may emit light of different respective wavelength bands. For example, the first sub-pixel SPX1 may emit light of a red wavelength band, the second sub-pixel SPX2 may emit light of a green wavelength band, and the third sub-pixel SPX3 may emit light of a blue wavelength band. However, the present disclosure is not limited thereto, and each of the first, second, and third sub-pixels SPX1, SPX2, and SPX3 may emit light of various wavelength bands.

The non-display area NAA may be an area that does not display an image. The non-display area NAA may be arranged around the display area AA. For example, the non-display area NAA may surround the display area AA in a plan view. The driver may be arranged in the non-display area NAA. For example, the driver may provide a signal and/or a voltage to the pixels PX. For example, the driver may include a gate driver GDV, a light-emitting driver EDV, a data driver DDV, and a controller CON.

Each of the pixels PX may be electrically connected to the gate driver GDV, the light-emitting driver EDV, and the data driver DDV. Each of the pixels PX may be connected to the gate driver GDV through a gate line GL, may be connected to the light-emitting driver EDV through a light-emitting line EML, and may be connected to the data driver DDV through a data line DL.

The gate driver GDV may receive a gate control signal GCTRL from the controller CON. The gate driver GDV may generate a gate signal GS based on the gate control signal GCTRL. The gate signal GS may be provided to each of the pixels PX through the gate line GL.

The light-emitting driver EDV may receive a light-emitting control signal ECTRL from the controller CON. The light-emitting driver EDV may generate a light-emitting signal EM based on the light-emitting control signal ECTRL. The light-emitting signal EM may be provided to each of the pixels PX through the light-emitting line EML.

The data driver DDV may receive a data control signal DCTRL and output image data ODAT from the controller CON. The data driver DDV may generate a data voltage DATA based on the data control signal DCTRL and the output image data ODAT. The data voltage DATA may be provided to each of the pixels PX through the data line DL.

The controller CON may receive both a control signal CTRL and input image data IDAT from an external device(s). The controller CON may generate the gate control signal GCTRL, the light-emitting control signal ECTRL, the data control signal DCTRL, and the output image data ODAT based on the control signal CTRL and the input image data IDAT. The controller CON may control the gate driver GDV, the light-emitting driver EDV, and the data driver DDV.

Although FIG. 1 illustrates that the gate driver GDV is arranged at a first side of the display device DD and the light-emitting driver EDV is arranged at a second side of the display device DD, the present disclosure is not limited thereto. For example, the gate driver GDV and the light-emitting driver EDV may be arranged together at the first side or the second side of the display device DD. For another example, the gate driver GDV and the light-emitting driver EDV may be integrally formed.

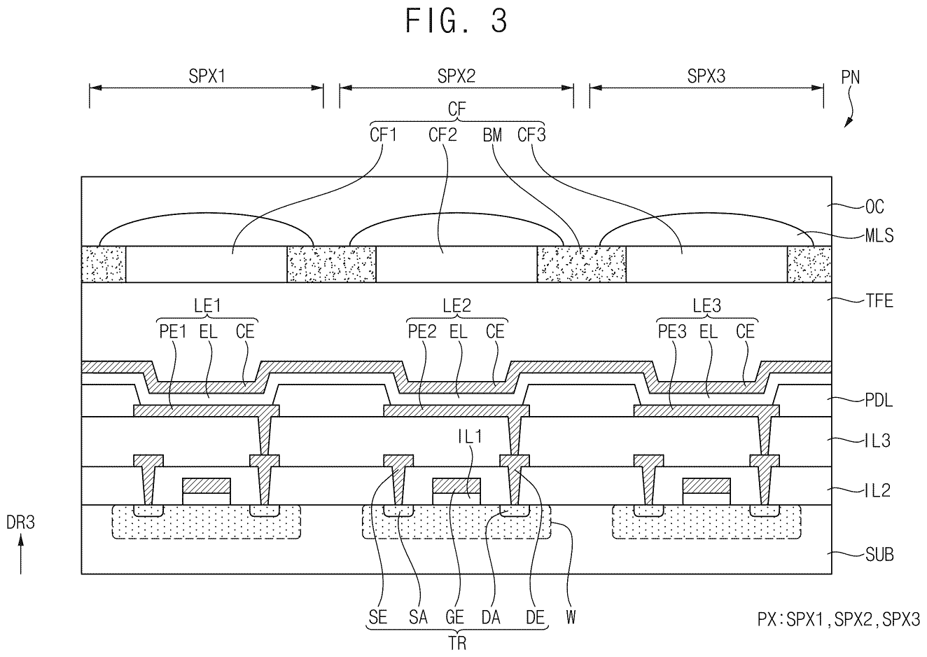

FIG. 3 is a cross-sectional view illustrating an example of a display panel included in the display device of FIG. 1. For example, FIG. 3 may be a cross-sectional view illustrating a portion of the display area AA of the display panel PN. For example, FIG. 3 may be a cross-sectional view of the pixel PX arranged in the display area AA.

Referring to FIGS. 1 and 3, the display panel PN may include a substrate SUB, a first insulating layer IL1, a second insulating layer IL2, a transistor TR, a first light-emitting element LE1, a second light-emitting element LE2, a third light-emitting element LE3, a pixel-defining layer PDL, an encapsulation layer TFE, a color filter layer CF, a micro-lens MLS, and a planarization layer OC.

The pixel PX arranged in the display area AA of the display panel DP may include the first sub-pixel SPX1, the second sub-pixel SPX2, and the third sub-pixel SPX3. The first, second, and third sub-pixels SPX1, SPX2, and SPX3 may be adjacent to each other. For example, the first, second, and third sub-pixels SPX1, SPX2, and SPX3 may emit light of different wavelength bands. The first sub-pixel SPX1 may include the transistor TR and the first light-emitting element LE1, the second sub-pixel SPX2 may include the transistor TR and the second light-emitting element LE2, and the third sub-pixel SPX3 may include the transistor TR and the third light-emitting element LE3.

The transistor TR may include a source area SA, a drain area DA, a gate electrode GE, a source electrode SE, and a drain electrode DE. The first light-emitting element LE1 may include a first pixel electrode PE1, a light-emitting layer EL, and a common electrode CE. The second light-emitting element LE2 may include a second pixel electrode PE2, the light-emitting layer EL, and the common electrode CE. The third light-emitting element LE3 may include a third pixel electrode PE3, the light-emitting layer EL, and the common electrode CE.

The substrate SUB may form a base of the display device DD. The substrate SUB may include a transparent or opaque material. The substrate SUB may include silicon, glass, quartz, plastic, or the like. These may be used alone or in combination with each other.

In one or more embodiments, the substrate SUB may be a silicon substrate. For example, the substrate SUB may be a p-type silicon substrate or an n-type silicon substrate. In this case, “p” may refer to a hole, and “n” may refer to an electron. The substrate SUB may include a well area W. The well area W may be a p-well area or an n-well area depending on a type of the transistor TR and a type of the substrate SUB.

The substrate SUB may include the source area SA and the drain area DA. For example, the source area SA and the drain area DA may be an n-source area and an n-drain area, respectively. However, the present disclosure is not limited thereto, and the source area SA and the drain area DA may be a p-source area and a p-drain area, respectively.

In one or more embodiments, the substrate SUB may be a polyimide substrate, a quartz substrate, a non-alkali glass substrate, or the like. In this case, the display device DD may further include a first active pattern, a second active pattern, and a third active pattern arranged on the substrate SUB and each including a semiconductor material.

The first insulating layer IL1 may be arranged on the substrate SUB (as used herein, “arranged on” may mean “above”). The first insulating layer IL1 may at least partially overlap the well area W in a plan view. The first insulating layer IL1 may include an inorganic material such as silicon oxide (SiOₓ), silicon nitride (SiNₓ), silicon oxynitride (SiOₓN_{y}), or the like. These may be used alone or in combination with each other.

The gate electrode GE may be arranged on the first insulating layer IL1. For example, the gate electrode GE may overlap the first insulating layer IL1 in a plan view. The gate electrode GE may include a metal, an alloy, a conductive metal oxide, a conductive metal nitride, a transparent conductive material, or the like. These may be used alone or in combination with each other.

The second insulating layer IL2 may be arranged on the substrate SUB. The second insulating layer IL2 may cover the gate electrode GE. The second insulating layer IL2 may include an inorganic material such as silicon oxide, silicon nitride, silicon oxynitride, or the like. These may be used alone or in combination with each other.

The source electrode SE and the drain electrode DE may be arranged on the second insulating layer IL2. The source electrode SE may be connected to the source area SA through a first contact hole penetrating a lower insulating layer (e.g., the second insulating layer IL2). The drain electrode DE may be connected to the drain area DA through a second contact hole penetrating a lower insulating layer (e.g., the second insulating layer IL2). The source electrode SE and the drain electrode DE may include a metal, an alloy, a metal oxide, a conductive metal nitride, a transparent conductive material, or the like. These may be used alone or in combination with each other.

Accordingly, the transistor TR including the source area SA, the drain area DA, the gate electrode GE, the source electrode SE, and the drain electrode DE may be arranged on the substrate SUB.

The third insulating layer IL3 may be arranged on the second insulating layer IL2. The third insulating layer IL3 may cover the source electrode SE and the drain electrode DE. The third insulating layer IL3 may include an organic insulating material, such as a phenol resin, an acrylic resin, a polyimide resin, a polyamide resin, a siloxane resin, an epoxy resin, or the like. These may be used alone or in combination with each other.

The first pixel electrode PE1, the second pixel electrode PE2, and the third pixel electrode PE3 may be arranged on the third insulating layer IL3. The first, second, and third pixel electrodes PE1, PE2 and PE3 may be spaced apart from each other.

Each of the first, second, and third pixel electrodes PE1, PE2, and PE3 may be electrically connected to the transistor TR. For example, each of the first, second, and third pixel electrodes PE1, PE2, and PE3 may be connected to the drain electrode DE (or the source electrode SE) through a contact hole penetrating a lower insulating layer (e.g., the third insulating layer IL3). The first, second, and third pixel electrodes PE1, PE2, and PE3 may include a metal, an alloy, a conductive metal oxide, a conductive metal nitride, a transparent conductive material, or the like. These may be used alone or in combination with each other.

For example, the first pixel electrode PE1 may operate as an anode of the first light-emitting element LE1, the second pixel electrode PE2 may operate as an anode of the second light-emitting element LE2, and the third pixel electrode PE3 may operate as an anode of the third light-emitting element LE3.

The pixel-defining layer PDL may be arranged on the third insulating layer IL3. The pixel-defining layer PDL may cover side portions of each of the first, second, and third pixel electrodes PE1, PE2 and PE3. For example, the pixel-defining layer PDL may define an opening exposing a portion of an upper surface of each of the first, second, and third pixel electrodes PE1, PE2 and PE3. The pixel-defining layer PDL may include an inorganic insulating material and/or an organic insulating material. These may be used alone or in combination with each other.

The light-emitting layer EL may be arranged on the first, second, and third pixel electrodes PE1, PE2, and PE3. The light-emitting layer EL may include a material that emits light of a selected color, and may include at least one of a hole injection layer, a hole transport layer, an electron injection layer, and an electron transport layer.

In one or more embodiments, the light-emitting layer EL of the first sub-pixel SPX1, the light-emitting layer EL of the second sub-pixel SPX2, and the light-emitting layer EL of the third sub-pixel SPX3 may be integrally formed. That is, the light-emitting layer EL may continuously extend in the first, second, and third sub-pixels SPX1, SPX2, and SPX3. However, the present disclosure is not limited thereto, and in one or more embodiments, the light-emitting layer EL may be separated in the first, second, and third sub-pixels SPX1, SPX2, and SPX3. That is, the light-emitting layer EL may be separated into a first light-emitting layer of the first sub-pixel SPX1, a second light-emitting layer of the second sub-pixel SPX2, and a third light-emitting layer of the third sub-pixel SPX3.

The common electrode CE may be arranged on the light-emitting layer EL. For example, the common electrode CE may continuously extend in the first, second, and third sub-pixels SPX1, SPX2, and SPX3. The common electrode CE may include a metal, an alloy, a conductive metal nitride, a conductive metal oxide, a transparent conductive material, or the like. These may be used alone or in combination with each other. For example, the common electrode CE may operate as a cathode of the first, second, and third light-emitting elements LE1, LE2, and LE3.

In one or more embodiments, the common electrode CE of the first sub-pixel SPX1, the common electrode CE of the second sub-pixel SPX2, and the common electrode CE of the third sub-pixel SPX3 may be integrally formed. That is, the common electrode CE may continuously extend in the first, second, and third sub-pixels SPX1, SPX2, and SPX3. However, the present disclosure is not limited thereto, and in one or more embodiments, the common electrode CE may be separated in the first, second, and third sub-pixels SPX1, SPX2, and SPX3. That is, the common electrode CE may be separated into a first common electrode of the first sub-pixel SPX1, a second common electrode of the second sub-pixel SPX2, and a third common electrode of the third sub-pixel SPX3.

Accordingly, the first light-emitting element LE1 including the first pixel electrode PE1, the light-emitting layer EL, and the common electrode CE, the second light-emitting element LE2 including the second pixel electrode PE2, the light-emitting layer EL, and the common electrode CE, and the third light-emitting element LE3 including the third pixel electrode PE3, the light-emitting layer EL, and the common electrode CE may be arranged on the substrate SUB.

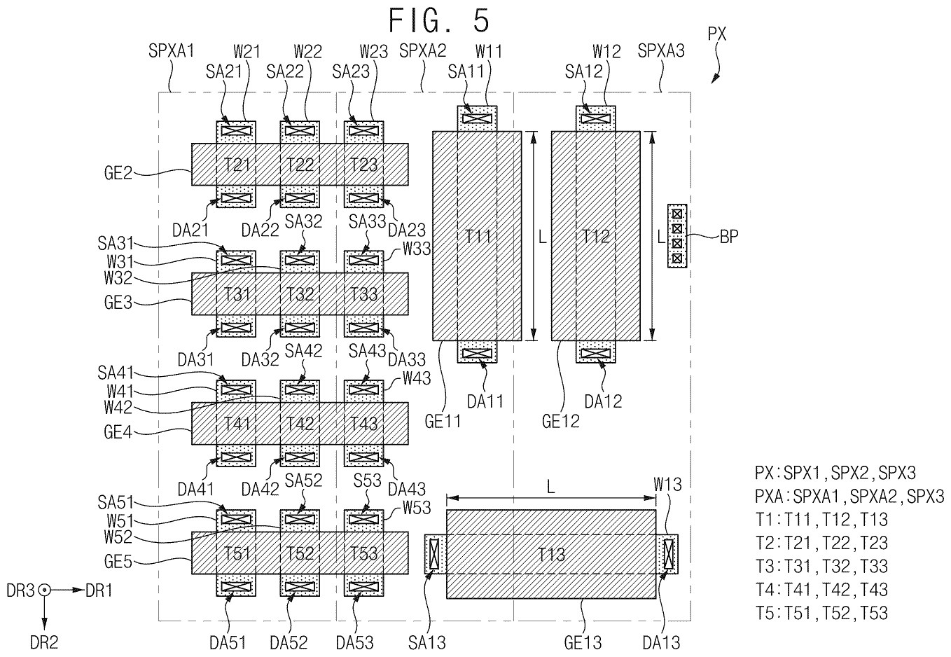

The first light-emitting element LE1 may be electrically connected to the transistor TR, and may generate light corresponding to a driving current provided from the transistor TR. The transistor TR and the first light-emitting element LE1 may correspond to the first sub-pixel SPX1. The first light-emitting element LE1 may define a first sub-pixel area (e.g., a first sub-pixel area SPXA1 of FIG. 5) in which the first sub-pixel SPX1 emits light.

The second light-emitting element LE2 may be electrically connected to the transistor TR, and may generate light corresponding to a driving current provided from the transistor TR. The transistor TR and the second light-emitting element LE2 may correspond to the second sub-pixel SPX2. The second light-emitting element LE2 may define a second sub-pixel area (e.g., a second sub-pixel area SPXA2 of FIG. 5) in which the second sub-pixel SPX2 emits light.

The third light-emitting element LE3 may be electrically connected to the transistor TR, and may generate light corresponding to a driving current provided from the transistor TR. The transistor TR and the third light-emitting element LE3 may correspond to the third sub-pixel SPX3. The third light-emitting element LE3 may define a third sub-pixel area (e.g., a third sub-pixel area SPXA3 of FIG. 5) in which the third sub-pixel SPX3 emits light.

The encapsulation layer TFE may be arranged on the common electrode CE. The encapsulation layer TFE may include at least one inorganic encapsulation layer and at least one organic encapsulation layer. For example, the encapsulation layer TFE may include a first inorganic layer, an organic layer, and a second inorganic layer sequentially stacked, but the present disclosure is not limited thereto. The encapsulation layer TFE may reduce or prevent impurities, moisture, or the like from penetrating into the first, second, and third light-emitting elements LE1, LE2, and LE3.

The color filter layer CF may be arranged on the encapsulation layer TFE. The color filter layer CF may include a first color filter CF1, a second color filter CF2, a third color filter CF3, and a partition wall BM.

The first color filter CF1 may overlap the first light-emitting element LE1 in a plan view, the second color filter CF2 may overlap the second light-emitting element LE2 in a plan view, and the third color filter CF3 may overlap the third light-emitting element LE3 in a plan view. That is, the first color filter CF1 may be arranged in the first sub-pixel area, the second color filter CF2 may be arranged in the second sub-pixel area, and the third color filter CF3 may be arranged in the third sub-pixel area.

Each of the first, second, and third color filters CF1, CF2, and CF3 may selectively transmit light of a corresponding wavelength band, and may absorb light of the remaining wavelength band. The first, second, and third color filters CF1, CF2, and CF3 may selectively transmit light of different wavelength bands. Accordingly, light of a wavelength band selectively transmitted by the first, second, and third color filters CF1, CF2, and CF3 may be emitted from the first, second, and third sub-pixel areas in which the first, second, and third sub-pixels SPX1, SPX2, and SPX3 emit light.

For example, the first color filter CF1 may selectively transmit light of a red wavelength band, the second color filter CF2 may selectively transmit light of a green wavelength band, and the third color filter CF3 may selectively transmit light of a blue wavelength band. Accordingly, light of a red wavelength band may be emitted from the first sub-pixel area, light of a green wavelength band may be emitted from the second sub-pixel area, and light of a blue wavelength band may be emitted from the third sub-pixel area, but the present disclosure is not limited thereto.

The partition wall BM may be arranged between the first, second, and third color filters CF1, CF2, and CF3 adjacent to each other. For example, the partition wall BM may be arranged between the first color filter CF1 and the second color filter CF2, may be arranged between the second color filter CF2 and the third color filter CF3, and may be arranged between the third color filter CF3 and the first color filter CF1. In one or more embodiments, the partition wall BM may include a light-blocking material. Examples of the light-blocking material may include an organic material or an inorganic material including a black pigment, a black dye, or the like. However, the present disclosure is not limited thereto, and the partition wall BM may include a reflective material, such as a metal. Accordingly, the partition wall BM may reduce or prevent color mixing between the first, second, and third sub-pixel areas.

The micro-lens MLS may be arranged on the color filter layer CF. The micro-lens MLS may have a selected refractive index, and may improve light extraction efficiency.

The planarization layer OC may be arranged on the micro-lens MLS. The planarization layer OC may include an organic material or an inorganic material. The planarization layer OC may compensate for a step difference due to components arranged below the planarization layer OC (e.g., the color filter layer CF, the micro-lens MLS, or the like).

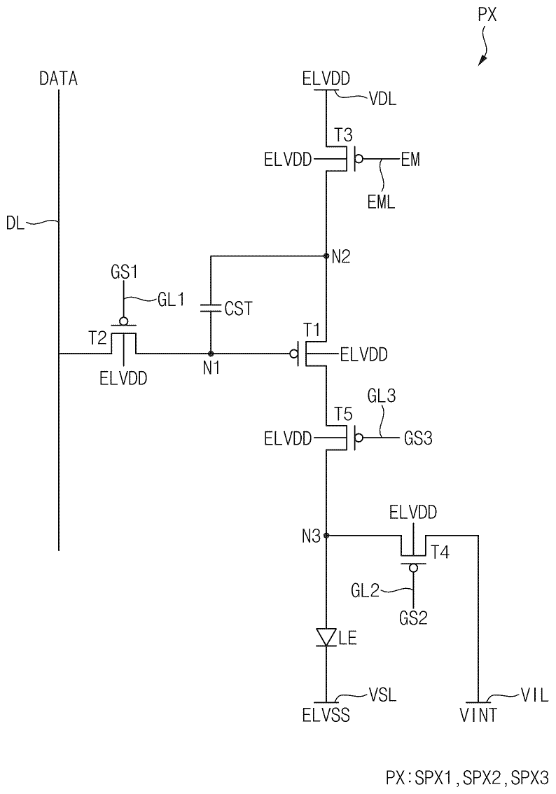

FIG. 4 is a circuit diagram illustrating an example of a pixel included in the display device of FIG. 1. For example, FIG. 4 may be a circuit diagram of one of the first, second, and third sub-pixels SPX1, SPX2, and SPX3 included in each of the pixels PX.

Referring to FIG. 4, each of the pixels PX may include a pixel circuit and a light-emitting element LE. The pixel circuit may include at least one thin film transistor and at least one capacitor. In one or more embodiments, the pixel circuit may include a first transistor T1, a second transistor T2, a third transistor T3, a fourth transistor T4, a fifth transistor T5, and a capacitor CST.

The first transistor T1 may include a gate electrode connected to a first node N1, a first electrode (e.g., a source) connected to a second node N2, and a second electrode (e.g., a drain). The first transistor T1 may generate a driving current applied to the light-emitting element LE according to a voltage of the gate electrode of the first transistor T1 (e.g., the first node N1). For example, the first transistor T1 may be referred to as a driving transistor. In one or more embodiments, the first transistor T1 may be a PMOS transistor, but the present disclosure is not limited thereto, and the first transistor T1 may be an NMOS transistor.

The second transistor T2 may include a gate electrode connected to a first gate line GL1 to receive a first gate signal GS1, a first electrode (e.g., a source) connected to the data line DL to receive the data voltage DATA, and a second electrode (e.g., a drain) connected to the first node N1. The second transistor T2 may provide the data voltage DATA to the gate electrode of the first transistor T1 in response to the first gate signal GS1. For example, the second transistor T2 may be referred to as a switching transistor. For example, the second transistor T2 may be a PMOS transistor, but the present disclosure is not limited thereto, and the second transistor T2 may be an NMOS transistor.

The third transistor T3 may include a gate electrode connected to the light-emitting line EML to receive the light-emitting signal EM, a first electrode (e.g., a source) connected to a first power line VDL to receive a first power voltage ELVDD, and a second electrode (e.g., a drain) connected to the second node N2. The first power voltage ELVDD may be a high (e.g., a relatively high voltage level) power supply voltage. The third transistor T3 may provide the first power voltage ELVDD to the first electrode of the first transistor T1 in response to the light-emitting signal EM. For example, the third transistor T3 may be referred to as a switching transistor. For example, the third transistor T3 may be a PMOS transistor, but the present disclosure is not limited thereto, and the third transistor T3 may be an NMOS transistor.

The fourth transistor T4 may include a gate electrode connected to a second gate line GL2 to receive a second gate signal GS2, a first electrode (e.g., source) connected to an initialization voltage line VIL to receive an initialization voltage VINT, and a second electrode (e.g., drain) connected to a third node N3. The fourth transistor T4 may provide the initialization voltage VINT to a first electrode (e.g., an anode) of the light-emitting element LE in response to the second gate signal GS2. For example, the fourth transistor T4 may be referred to as a switching transistor. For example, the fourth transistor T4 may be a PMOS transistor, but the present disclosure is not limited thereto, and the fourth transistor T4 may be an NMOS transistor.

The fifth transistor T5 may include a gate electrode connected to a third gate line GL3 to receive a third gate signal GS3, a first electrode (e.g., source) connected to the second electrode of the first transistor T1, and a second electrode (e.g., drain) connected to the third node N3. The fifth transistor T5 may electrically connect the second electrode of the first transistor T1 and the first electrode of the light-emitting element LE in response to the third gate signal GS3. Accordingly, the driving current generated from the first transistor T1 may be applied to the light-emitting element LE. For example, the fifth transistor T5 may be referred to as a switching transistor. For example, the fifth transistor T5 may be a PMOS transistor, but the present disclosure is not limited thereto, and the fifth transistor T5 may be an NMOS transistor.

The capacitor CST may include a first electrode connected to the first node N1 and a second electrode connected to the second node N2. The capacitor CST may serve to receive the data voltage DATA from the second transistor T2 and store the received data voltage DATA. For example, the capacitor CST may be referred to as a storage capacitor.

The light-emitting element LE may include the first electrode connected to the third node N3 and a second electrode (e.g., a cathode) connected to a second power line VSL to receive a second power voltage ELVSS. The second power voltage ELVSS may be a low (e.g., a relatively low voltage level) power voltage. The second power voltage ELVSS may have a lower level than the first power voltage ELVDD. The light-emitting element LE may emit light with a luminance corresponding to the driving current generated and applied from the first transistor T1.

In one or more embodiments, each of the first, second, third, fourth, and fifth transistors T1, T2, T3, T4, and T5 may further include a back-gate electrode. Each of the back-gate electrodes of the first, second, third, fourth, and fifth transistors T1, T2, T3, T4, and T5 may receive the first power voltage ELVDD.

Although FIG. 4 illustrates that the pixel PX (e.g., each of the first, second, and third sub-pixels SPX1, SPX2, and SPX3) includes five transistors, one capacitor, and one light-emitting element, but the present disclosure is not limited thereto. The pixel PX may include one or more transistors, one or more capacitors, and one or more light-emitting elements.

FIG. 5 is a plan view illustrating an example of a pixel included in the display device of FIG. 1.

Referring to FIG. 5, the pixel PX may include the first, second, and third subpixels SPX1, SPX2, and SPX3 and a body pattern BP.

An area in which the first sub-pixel SPX1 emits light may be defined as a first sub-pixel area SPXA1, an area in which the second sub-pixel SPX2 emits light may be defined as a second sub-pixel area SPXA2, and an area in which the third sub-pixel SPX3 emits light may be defined as a third sub-pixel area SPXA3. The first, second, and third sub-pixel areas SPXA1, SPXA2, and SPXA3 may be adjacent to each other.

For example, the second sub-pixel area SPXA2 may be adjacent to the first sub-pixel area SPXA1 in the first direction DR1, and the third sub-pixel area SPXA3 may be adjacent to the second sub-pixel area SPXA2 in the first direction DR1. However, the present disclosure is not limited thereto, and the arrangement of the first, second, and third sub-pixel areas SPXA1, SPXA2, and SPXA3 may be variously changed.

The first, second, and third sub-pixel areas SPXA1, SPXA2, and SPXA3 may be areas that emit light of different respective wavelength bands. For example, the first sub-pixel area SPXA1 may be an area that emits light of a red wavelength band, the second sub-pixel area SPXA2 may be an area that emits light of a green wavelength band, and the third sub-pixel area SPXA3 may be an area that emits light of a blue wavelength band. However, the present disclosure is not limited thereto, and each of the first, second, and third sub-pixel areas SPXA1, SPXA2, and SPXA3 may be an area that emits light of various wavelength bands.

The first, second, and third sub-pixel areas SPXA1, SPXA2, and SPXA3 may define a pixel area PXA. The pixel area PXA may be defined as an area in which the pixel PX emits light. The pixel area PXA may be repeatedly arranged in the first direction DR1 and in the second direction DR2 in the display area AA. A unit repeating along the first direction DR1 and the second direction DR2 may be defined as the pixel area PXA.

The first sub-pixel SPX1 may include a first first transistor T11 (e.g., a first driving transistor in the claims, hereinafter, will be referred to as “(1-1)th transistor”), a first second transistor T21 (e.g., a first switching transistor in the claims, hereinafter, will be referred to as “(2-1)th transistor”), a first third transistor T31 (hereinafter, will be referred to as “(3-1)th transistor”), a first fourth transistor T41 (e.g., a fourth switching transistor in the claims, hereinafter, will be referred to as “(4-1)th transistor”), and a first fifth transistor T51 (hereinafter, will be referred to as “(5-1)th transistor”).

The second sub-pixel SPX2 may include a second first transistor T12 (e.g., a second driving transistor in the claims, hereinafter, will be referred to as “(1-2)th transistor”), a second second transistor T22 (e.g., a second switching transistor in the claims, hereinafter, will be referred to as “(2-2)th transistor”), a second third transistor T32 (hereinafter, will be referred to as “(3-2)th transistor”), a second fourth transistor T42 (e.g., a fifth switching transistor in the claims, hereinafter, will be referred to as “(4-2)th transistor”), and a second fifth transistor T52 (hereinafter, will be referred to as “(5-2)th transistor”).

The third sub-pixel SPX3 may include a third first transistor T13 (e.g., a third driving transistor in the claims, hereinafter, will be referred to as “(1-3)th transistor”), a third second transistor T23 (e.g., a third switching transistor in the claims, hereinafter, will be referred to as “(2-3)th transistor”), a third third transistor T33 (hereinafter, will be referred to as “(3-3)th transistor”), a third fourth transistor T43 (e.g., a sixth switching transistor in the claims, hereinafter, will be referred to as “(4-3)th transistor”), and a third fifth transistor T53 (hereinafter, will be referred to as “(5-3)th transistor”).

Each of the (1-1)th, (1-2)th, and (1-3)th transistors T11, T12, and T13 may correspond to the first transistor T1 (e.g., the driving transistor) of FIG. 4. Each of the (2-1)th, (2-2)th, and (2-3)th transistors T21, T22, and T23 may correspond to the second transistor T2 (e.g., the switching transistor) of FIG. 4. Each of the (3-1)th, (3-2)th and (3-3)th transistors T31, T32, and T33 may correspond to the third transistor T3 (e.g., the switching transistor) of FIG. 4. Each of the (4-1)th, (4-2)th, and (4-3)th transistors T41, T42, and T43 may correspond to the fourth transistor T4 (e.g., the switching transistor) of FIG. 4. Each of the (5-1)th, (5-2)th, and (5-3)th transistors T51, T52, and T53 may correspond to the fifth transistor T5 (e.g., the switching transistor) of FIG. 4.

At least a portion of the (1-1)th, (2-1)th, (3-1)th, (4-1)th, and (5-1)th transistors T11, T21, T31, T41, and T51 of the first sub-pixel SPX1 might not be arranged in the first sub-pixel area SPXA1 (as used herein, “a portion of” may mean “one or more of” or “a portion of one or more of”). At least a portion of the (1-1)th, (2-1)th, (3-1)th, (4-1)th, and (5-1)th transistors T11, T21, T31, T41, and T51 may be arranged in the second sub-pixel area SPXA2 and/or the third sub-pixel area SPXA3. For example, referring to FIG. 5, the (1-1)th transistor T11 may be arranged in the second sub-pixel area SPXA2, and the (2-1)th, (3-1)th, (4-1)th, and (5-1)th transistors T21, T31, T41, and T51 may be arranged in the first sub-pixel area SPXA1. However, the present disclosure is not limited thereto, and an area in which the transistors of the first sub-pixel SPX1 are arranged may be variously changed. That is, the first sub-pixel area SPXA1 might not be defined as an area in which the (1-1)th, (2-1)th, (3-1)th, (4-1)th, and (5-1)th transistors T11, T21, T31, T41, and T51 are arranged.

At least a portion of the (1-2)th, (2-2)th, (3-2)th, (4-2)th, and (5-2)th transistors T12, T22, T32, T42, and T52 of the second sub-pixel SPX2 might not be arranged in the second sub-pixel area SPXA2. At least a portion of the (1-2)th, (2-2)th, (3-2)th, (4-2)th, and (5-2)th transistors T12, T22, T32, T42, and T52 may be arranged in the first sub-pixel area SPXA1 and/or the third sub-pixel area SPXA3. For example, referring to FIG. 5, the (1-2)th transistor T12 may be arranged in the third sub-pixel area SPXA3, and the (2-2)th, (3-2)th, (4-2)th, and (5-2)th transistors T22, T32, T42, and T52 may be arranged in the first sub-pixel area SPXA1. However, the present disclosure is not limited thereto, and an area in which the transistors of the second sub-pixel SPX2 are arranged may be variously changed. That is, the second sub-pixel area SPXA2 might not be defined as an area in which the (1-2)th, (2-2)th, (3-2)th, (4-2)th, and (5-2)th transistors T12, T22, T32, T42, and T52 are arranged.

At least a portion of the (1-3)th, (2-3)th, (3-3)th, (4-3)th, and (5-3)th transistors T13, T23, T33, T43, and T53 of the third sub-pixel SPX3 might not be arranged in the third sub-pixel area SPXA3. At least a portion of the (1-3)th, (2-3)th, (3-3)th, (4-3)th, and (5-3)th transistors T13, T23, T33, T43, and T53 may be arranged in the first sub-pixel area SPXA1 and/or the second sub-pixel area SPXA2. For example, referring to FIG. 5, the (1-3)th transistor T13 may be arranged in the second and third sub-pixel areas SPXA2 and SPXA3, and the (2-3)th, (3-3)th, (4-3)th, and (5-3)th transistors T23, T33, T43, and T53 may be arranged in the second sub-pixel area SPXA2. However, the present disclosure is not limited thereto, and an area in which the transistors of the third sub-pixel SPX3 are arranged may be variously changed. That is, the third sub-pixel area SPXA3 might not be defined as an area in which the (1-3)th, (2-3)th, (3-3)th, (4-3)th, and (5-3)th transistors T13, T23, T33, T43, and T53 are arranged.

A first first well area W11 (e.g., a first well area in the claims, hereinafter, will be referred to as “(1-1)th well area”) and a first first gate electrode GE11 (e.g., a first gate electrode in the claims, hereinafter, will be referred to as “(1-1)th gate electrode”) may define the (1-1)th transistor T11. The (1-1)th well area W11 and the (1-1)th gate electrode GE11 may at least partially overlap in a plan view. The (1-1)th well area W11 may include a first first source area SA11 (hereinafter, will be referred to as “(1-1)th source area”) and a first first drain area DA11 (hereinafter, will be referred to as “(1-1)th drain area”). The (1-1)th source area SA11 may be an area in which the (1-1)th well area W11 and a source electrode (e.g., the source electrode SE of FIG. 3) of the (1-1)th transistor T11 are connected, and the (1-1)th drain area DA11 may be an area in which the (1-1)th well area W11 and a drain electrode (e.g., the drain electrode DE of FIG. 3) of the (1-1)th transistor T11 are connected.

The (1-1)th source area SA11 and the (1-1)th drain area DA11 may be defined in an area in which the (1-1)th well area W11 and the (1-1)th gate electrode GE11 do not overlap in a plan view. For example, the (1-1)th gate electrode GE11 may be arranged between the (1-1)th source area SA11 and the (1-1)th drain area DA11 in a plan view.

A second first well area W12 (e.g., a third well area in the claims, hereinafter, will be referred to as “(1-2)th well area”) and a second first gate electrode GE12 (e.g., a third gate electrode in the claims, hereinafter, will be referred to as “(1-2)th gate electrode”) may define the (1-2)th transistor T12. The (1-2)th well area W12 and the (1-2)th gate electrode GE12 may at least partially overlap in a plan view. The (1-2)th well area W12 may include a second first source area SA12 (hereinafter, will be referred to as “(2-1)th source area”) and a second first drain area DA12 (hereinafter, will be referred to as “(2-1)th drain area”). The (1-2)th source area SA12 may be an area in which the (1-2)th well area W12 and a source electrode (e.g., the source electrode SE of FIG. 3) of the (1-2)th transistor T12 are connected, and the (1-2)th drain area DA12 may be an area in which the (1-2)th well area W12 and a drain electrode (e.g., the drain electrode DE of FIG. 3) of the (1-2)th transistor T12 are connected.

The (1-2)th source area SA12 and the (1-2)th drain area DA12 may be defined in an area in which the (1-2)th well area W12 and the (1-2)th gate electrode GE12 do not overlap in a plan view. For example, the (1-2)th gate electrode GE12 may be arranged between the (1-2)th source area SA12 and the (1-2)th drain area DA12 in a plan view.

A third first well area W13 (e.g., a fifth well area in the claims, hereinafter, will be referred to as “(1-3)th well area”) and a third first gate electrode GE13 (e.g., a fifth gate electrode in the claims, hereinafter, will be referred to as “(1-3)th gate electrode”) may define the (1-3)th transistor T13. The (1-3)th well area W13 and the (1-3)th gate electrode GE13 may at least partially overlap in a plan view. The (1-3)th well area W13 may include a third first source area SA13 (hereinafter, will be referred to as “(1-3)th source area”) and a third first drain area DA13 (hereinafter, will be referred to as “(1-3)th drain area”). The (1-3)th source area SA13 may be an area in which the (1-3)th well area W13 and a source electrode (e.g., the source electrode SE of FIG. 3) of the (1-3)th transistor T13 are connected, and the (1-3)th drain area DA13 may be an area in which the (1-3)th well area W13 and a drain electrode (e.g., the drain electrode DE of FIG. 3) of the (1-3)th transistor T13 are connected.

The (1-3)th source area SA13 and the (1-3)th drain area DA13 may be defined in an area in which the (1-3)th well area W13 and the (1-3)th gate electrode GE13 do not overlap in a plan view. For example, the (1-3)th gate electrode GE13 may be arranged between the (1-3)th source area SA13 and the (1-3)th drain area DA13 in a plan view.

In one or more embodiments, the (1-1)th, (1-2)th, and (1-3)th well areas W11, W12, and W13 may be spaced apart from each other. In one or more embodiments, the (1-1)th, (1-2)th, and (1-3)th gate electrodes GE11, GE12, and GE13 may be spaced apart from each other.

A first second well area W21 (e.g., a second well area in the claims, hereinafter, will be referred to as “(2-1)th well area”) and a second gate electrode GE2 (e.g., a second gate electrode, a fourth gate electrode, and/or a sixth gate electrode in the claims) may define the (2-1)th transistor T21. The (2-1)th well area W21 and the second gate electrode GE2 may at least partially overlap in a plan view. The (2-1)th well area W21 may include a first second source area SA21 (hereinafter, will be referred to as “(2-1)th source area”) and a first second drain area DA21 (hereinafter, will be referred to as “(2-1)th drain area”). The (2-1)th source area SA21 may be an area in which the (2-1)th well area W21 and a source electrode (e.g., the source electrode SE of FIG. 3) of the (2-1)th transistor T21 are connected, and the (2-1)th drain area DA21 may be an area in which the (2-1)th well area W21 and a drain electrode (e.g., the drain electrode DE of FIG. 3) of the (2-1)th transistor T21 are connected.

The (2-1)th source area SA21 and the (2-1)th drain area DA21 may be defined in an area in which the (2-1)th well area W21 and the second gate electrode GE2 do not overlap in a plan view. For example, the second gate electrode GE2 may be arranged between the (2-1)th source area SA21 and the (2-1)th drain area DA21 in a plan view.

A second second well area W22 (e.g., a fourth well area in the claims, hereinafter, will be referred to as “(2-2)th well area”) and the second gate electrode GE2 may define the (2-2)th transistor T22. The (2-2)th well area W22 and the second gate electrode GE2 may at least partially overlap in a plan view. The (2-2)th well area W22 may include a second second source area SA22 (hereinafter, will be referred to as “(2-2)th source area”) and a second second drain area DA22 (hereinafter, will be referred to as “(2-2)th drain area”). The (2-2)th source area SA22 may be an area in which the (2-2)th well area W22 and a source electrode (e.g., the source electrode SE of FIG. 3) of the (2-2)th transistor T22 are connected, and the (2-2)th drain area DA22 may be an area in which the (2-2)th well area W22 and a drain electrode (e.g., the drain electrode DE of FIG. 3) of the (2-2)th transistor T22 are connected.

The (2-2)th source area SA22 and the (2-2)th drain area DA22 may be defined in an area in which the (2-2)th well area W22 and the second gate electrode GE2 do not overlap in a plan view. For example, the second gate electrode GE2 may be arranged between the (2-2)th source area SA22 and the (2-2)th drain area DA22 in a plan view.

A third second well area W23 (e.g., a sixth well area in the claims, hereinafter, will be referred to as “(2-3)th well area”) and the second gate electrode GE2 may define the (2-3)th transistor T23. The (2-3)th well area W23 and the second gate electrode GE2 may at least partially overlap in a plan view. The (2-3)th well area W23 may include a third second source area SA23 (hereinafter, will be referred to as “(2-3)th source area”) and a third second drain area DA23 (hereinafter, will be referred to as “(2-3)th drain area”). The (2-3)th source area SA23 may be an area in which the (2-3)th well area W23 and a source electrode (e.g., the source electrode SE of FIG. 3) of the (2-3)th transistor T23 are connected, and the (2-3)th drain area DA23 may be an area in which the (2-3)th well area W23 and a drain electrode (e.g., the drain electrode DE of FIG. 3) of the (2-3)th transistor T23 are connected.

The (2-3)th source area SA23 and the (2-3)th drain area DA23 may be defined in an area in which the (2-3)th well area W23 and the second gate electrode GE2 do not overlap in a plan view. For example, the second gate electrode GE2 may be arranged between the (2-3)th source area SA23 and the (2-3)th drain area DA23 in a plan view.

In one or more embodiments, the (2-1)th, (2-2)th, and (2-3)th well areas W21, W22, and W23 may be spaced apart from each other. In one or more embodiments, the (2-1)th, (2-2)th, and (2-3)th transistors T21, T22, and T23 may share the second gate electrode GE2. The gate electrodes of the (2-1)th, (2-2)th, and (2-3)th transistors T21, T22, and T23 may be connected to each other. That is, the gate electrodes of the (2-1)th, (2-2)th, and (2-3)th transistors T21, T22, and T23 may be integral. One second gate electrode GE2 may extend to at least partially overlap each of the (2-1)th, (2-2)th, and (2-3)th well areas W21, W22, and W23 in a plan view. Accordingly, the second transistors T2 of the first, second, and third sub-pixels SPX1, SPX2, and SPX3 may be arranged adjacent to each other. As the second transistors T2 of the first, second, and third sub-pixels SPX1, SPX2, and SPX3 are arranged together, an area occupied by the second transistors T2 in the first, second, and third sub-pixel areas SPXA1, SPXA2, and SPXA3 may be reduced.

A first third well area W31 (hereinafter, will be referred to as “(3-1)th well area”) and a third gate electrode GE3 may define the (3-1)th transistor T31. The (3-1)th well area W31 and the third gate electrode GE3 may at least partially overlap in a plan view. The (3-1)th well area W31 may include a first third source area SA31 (hereinafter, will be referred to as “(3-1)th source area”) and a first third drain area DA31 (hereinafter, will be referred to as “(3-1)th drain area”). The (3-1)th source area SA31 may be an area in which the (3-1)th well area W31 and a source electrode (e.g., the source electrode SE of FIG. 3) of the (3-1)th transistor T31 are connected, and the (3-1)th drain area DA31 may be an area in which the (3-1)th well area W31 and a drain electrode (e.g., the drain electrode DE of FIG. 3) of the (3-1)th transistor T31 are connected.

The (3-1)th source area SA31 and the (3-1)th drain area DA31 may be defined in an area in which the (3-1)th well area W31 and the third gate electrode GE3 do not overlap in a plan view. For example, the third gate electrode GE3 may be arranged between the (3-1)th source area SA31 and the (3-1)th drain area DA31 in a plan view.

A second third well area W32 (hereinafter, will be referred to as “(3-2)th well area”) and the third gate electrode GE3 may define the (3-2)th transistor T32. The (3-2)th well area W32 and the third gate electrode GE3 may at least partially overlap in a plan view. The (3-2)th well area W32 may include a second third source area SA32 (hereinafter, will be referred to as “(3-2)th source area”) and a second third drain area DA32 (hereinafter, will be referred to as “(3-2)th drain area”). The (3-2)th source area SA32 may be an area in which the (3-2)th well aera W32 and a source electrode (e.g., the source electrode SE of FIG. 3) of the (3-2)th transistor T32 are connected, and the (3-2)th drain area DA32 may be an area in which the (3-2)th well area W32 a drain electrode (e.g., the drain electrode DE of FIG. 3) of the (3-2)th transistor T32 are connected.

The (3-2)th source area SA32 and the (3-2)th drain area DA32 may be defined in an area in which the (3-2)th well area W32 and the third gate electrode GE3 do not overlap in a plan view. For example, the third gate electrode GE3 may be arranged between the (3-2)th source area SA32 and the (3-2)th drain area DA32 in a plan view.

A third third well area W33 (hereinafter, will be referred to as “(3-3)th well area”) and the third gate electrode GE3 may define the (3-3)th transistor T33. The (3-3)th well area W33 and the third gate electrode GE3 may at least partially overlap in a plan view. The (3-3)th well area W33 may include a third third source aera SA33 (hereinafter, will be referred to as “(3-3)th source area”) and a third third drain area DA33 (hereinafter, will be referred to as “(3-3)th drain area”). The (3-3)th source area SA33 may be an area in which the (3-3)th well area W33 and a source electrode (e.g., the source electrode SE of FIG. 3) of the (3-3)th transistor T33 are connected, and the (2-3)th drain area DA23 may be an area in which the (3-3)th well area W33 and a drain electrode (e.g., the drain electrode DE of FIG. 3) of the (3-3)th transistor T33 are connected.

The (3-3)th source area SA33 and the (3-3)th drain area DA33 may be defined in an area in which the (3-3)th well area W33 and the third gate electrode GE3 do not overlap in a plan view. For example, the third gate electrode GE3 may be arranged between the (3-3)th source area SA33 and the (3-3)th drain area DA33 in a plan view.

In one or more embodiments, the (3-1)th, (3-2)th, and (3-3)th well areas W31, W32, and W33 may be spaced apart from each other. In one or more embodiments, the (3-1)th, (3-2)th, and (3-3)th transistors T31, T32, and T33 may share the third gate electrode GE3. The gate electrodes of the (3-1)th, (3-2)th, and (3-3)th transistors T31, T32, and T33 may be connected to each other. That is, the gate electrodes of the (3-1)th, (3-2)th, and (3-3)th transistors T31, T32, and T33 may be integral. One third gate electrode GE3 may extend to at least partially overlap each of the (3-1)th, (3-2)th, and (3-3)th well areas W31, W32, and W33 in a plan view. Accordingly, the third transistors T3 of the first, second, and third sub-pixels SPX1, SPX2, and SPX3 may be arranged adjacent to each other. As the third transistors T3 of the first, second, and third sub-pixels SPX1, SPX2, and SPX3 are arranged together, an area occupied by the third transistors T3 in the first, second, and third sub-pixel areas SPXA1, SPXA2, and SPXA3 may be reduced.

A first fourth well area W41 (hereinafter, will be referred to as “(4-1)th well area”) and a fourth gate electrode GE4 may define the (4-1)th transistor T41. The (4-1)th well area W41 and the fourth gate electrode GE4 may at least partially overlap in a plan view. The (4-1)th well area W41 may include a first fourth source area SA41 (hereinafter, will be referred to as “(4-1)th source area”) and a first fourth drain area DA41 (hereinafter, will be referred to as “(4-1)th drain area”). The (4-1)th source area SA41 may be an area in which the (4-1)th well area W41 and a source electrode (e.g., the source electrode SE of FIG. 3) of the 4-1yj transistor T41 are connected, and the (3-1)th drain area DA31 may be an area in which the (4-1)th well area W41 and a drain electrode (e.g., the drain electrode DE of FIG. 3) of the (4-1)th transistor T41 are connected.

The (4-1)th source area SA41 and the (4-1)th drain area DA41 may be defined in an area in which the (4-1)th well area W41 and the fourth gate electrode GE4 do not overlap in a plan view. For example, the fourth gate electrode GE4 may be arranged between the (4-1)th source area SA41 and the (4-1)th drain area DA41 in a plan view.

A second fourth well area W42 (hereinafter, will be referred to as “(4-2)th well area”) and the fourth gate electrode GE4 may define the (4-2)th transistor T42. The (4-2)th well area W42 and the fourth gate electrode GE4 may at least partially overlap in a plan view. The (4-2)th well area W42 may include a second fourth source area SA42 (hereinafter, will be referred to as “(4-2)th source area”) and a second fourth drain area DA42 (hereinafter, will be referred to as “(4-2)th drain area”). The (4-2)th source area SA42 may be an area in which the (4-2)th well area W42 and a source electrode (e.g., the source electrode SE of FIG. 3) of the (4-2)th transistor T42 are connected, and the (4-2)th drain area DA42 may be an area in which the (4-2)th well area W42 and a drain electrode (e.g., the drain electrode DE of FIG. 3) of the (4-2)th transistor T42 are connected.

The (4-2)th source area SA42 and the (4-2)th drain area DA42 may be defined in an area in which the (4-2)th well area W42 and the fourth gate electrode GE4 do not overlap in a plan view. For example, the fourth gate electrode GE4 may be arranged between the (4-2)th source area SA42 and the (4-2)th drain area DA42 in a plan view.

A third fourth well area W43 (hereinafter, will be referred to as “(4-3)th well area”) and the fourth gate electrode GE4 may define the (4-3)th transistor T43. The (4-3)th well area W43 and the fourth gate electrode GE4 may at least partially overlap in a plan view. The (4-3)th well area W43 may include a third fourth source area SA43 (hereinafter, will be referred to as “(4-3)th source area”) and a third fourth drain area DA43 (hereinafter, will be referred to as “(4-3)th drain area”). The (4-3)th source area SA43 may be an area in which the (4-3)th well area W43 and a source electrode (e.g., the source electrode SE of FIG. 3) of the (4-3)th transistor T43 are connected, and the (2-3)th drain area DA23 may be an area in which the (4-3)th well area W43 and a drain electrode (e.g., the drain electrode DE of FIG. 3) of the (4-3)th transistor T43 are connected.

The (4-3)th source area SA43 and the (4-3)th drain area DA43 may be defined in an area in which the (4-3)th well area W43 and the fourth gate electrode GE4 do not overlap in a plan view. For example, the fourth gate electrode GE4 may be arranged between the (4-3)th source area SA43 and the (4-3)th drain area DA43 in a plan view.

In one or more embodiments, the (4-1)th, (4-2)th, and (4-3)th well areas W41, W42, and W43 may be spaced apart from each other. In one or more embodiments, the (4-1)th, (4-2)th, and (4-3)th transistors T41, T42, and T43 may share the fourth gate electrode GE4. The gate electrodes of the (4-1)th, (4-2)th, and (4-3)th transistors T41, T42, and T43 may be connected to each other. That is, the gate electrodes of the (4-1)th, (4-2)th, and (4-3)th transistors T41, T42, and T43 may be integral. One fourth gate electrode GE4 may extend to at least partially overlap each of the (4-1)th, (4-2)th, and (4-3)th well areas W41, W42, and W43 in a plan view. Accordingly, the fourth transistors T4 of the first, second, and third sub-pixels SPX1, SPX2, and SPX3 may be arranged adjacent to each other. As the fourth transistors T4 of the first, second, and third sub-pixels SPX1, SPX2, and SPX3 are arranged together, an area occupied by the fourth transistors T4 in the first, second, and third sub-pixel areas SPXA1, SPXA2, and SPXA3 may be reduced.

A first fifth well area W51 (hereinafter, will be referred to as “(5-1)th well area”) and a fifth gate electrode GE5 may define the (5-1)th transistor T51. The (5-1)th well area W51 and the fifth gate electrode GE5 may at least partially overlap in a plan view. The (5-1)th well area W51 may include a first fifth source area SA51 (hereinafter, will be referred to as “(5-1)th source area”) and a first fifth drain area DA51 (hereinafter, will be referred to as “(5-1)th drain area”). The (5-1)th source area SA51 may be an area in which the (5-1)th well area W51 and a source electrode (e.g., the source electrode SE of FIG. 3) of the (5-1)th transistor T51 are connected, and the (5-1)th drain area DA51 may be an area in which the (5-1)th well area W51 and a drain electrode (e.g., the drain electrode DE of FIG. 3) of the (5-1)th transistor T51 are connected.

The (5-1)th source area SA51 and the (5-1)th drain area DA51 may be defined in an area in which the (5-1)th well area W51 and the fifth gate electrode GE5 do not overlap in a plan view. For example, the fifth gate electrode GE5 may be arranged between the (5-1)th source area SA51 and the (5-1)th drain area in a plan view.

A second fifth well area W52 (hereinafter, will be referred to as “(5-2)th well area”) and the fifth gate electrode GE5 may define the (5-2)th transistor T52. The (5-2)th well area W52 and the fifth gate electrode GE5 may at least partially overlap in a plan view. The (5-2)th well area W52 may include a second fifth source area SA52 (hereinafter, will be referred to as “(5-2)th source area”) and a second fifth drain area DA52 (hereinafter, will be referred to as “(5-2)th drain area”). The (5-2)th source area SA52 may be an area in which the (5-2)th well area W52 and a source electrode (e.g., the source electrode SE of FIG. 3) of the (5-2)th transistor T52 are connected, and the (5-2)th drain area DA52 may be an area in which the (5-2)th well area W52 and a drain electrode (e.g., the drain electrode DE of FIG. 3) of the (5-2)th transistor T52 are connected.

The (5-2)th source area SA52 and the (5-2)th drain area DA52 may be defined in an area in which the (5-2)th well area W52 and the fifth gate electrode GE5 do not overlap in a plan view. For example, the fifth gate electrode GE5 may be arranged between the (5-2)th source area SA52 and the (5-2)th drain area DA52 in a plan view.

A third fifth well area W53 (hereinafter, will be referred to as “(5-3)th well area”) and the fifth gate electrode GE5 may define the (5-3)th transistor T53. The (5-3)th well area W53 and the fifth gate electrode GE5 may at least partially overlap in a plan view. The (5-3)th well area W53 may include a third fifth source area SA53 (hereinafter, will be referred to as “(5-3)th source area”) and a third fifth drain area DA53 (hereinafter, will be referred to as “(5-3)th drain area”). The (5-3)th source area SA53 may be an area in which the (5-3)th well area W53 and a source electrode (e.g., the source electrode SE of FIG. 3) of the (5-3)th transistor T53 are connected, and the (5-3)th drain area DA53 may be an area in which the (5-3)th well area W53 and a drain electrode (e.g., the drain electrode DE of FIG. 3) of the (5-3)th transistor T53 are connected.

The (5-3)th source area SA53 and the (5-3)th drain area DA53 may be defined in an area in which the (5-3)th well area W53 and the fifth gate electrode GE5 do not overlap in a plan view. For example, the fifth gate electrode GE5 may be arranged between the (5-3)th source area SA53 and the (5-3)th drain area DA53 in a plan view.

In one or more embodiments, the (5-1)th, (5-2)th, and (5-3)th well areas W51, W52, and W53 may be spaced apart from each other. In one or more embodiments, the (5-1)th, (5-2)th, and (5-3)th transistors T51, T52, and T53 may share the fifth gate electrode GE5. The gate electrodes of the (5-1)th, (5-2)th, and (5-3)th transistors T51, T52, and T53 may be connected to each other. That is, the gate electrodes of the (5-1)th, (5-2)th, and (5-3)th transistors T51, T52, and T53 may be integral. One fifth gate electrode GE5 may extend to at least partially overlap each of the (5-1)th, (5-2)th, and (5-3)th well areas W51, W52, and W53 in a plan view. Accordingly, the fifth transistors T5 of the first, second, and third sub-pixels SPX1, SPX2, and SPX3 may be arranged adjacent to each other. As the fifth transistors T5 of the first, second, and third sub-pixels SPX1, SPX2, and SPX3 are arranged together, an area occupied by the fifth transistors T5 in the first, second, and third sub-pixel areas SPXA1, SPXA2, and SPXA3 may be reduced.

In one or more embodiments, a size of the first transistor T1 may be relatively greater than a size of each of the second, third, fourth, and fifth transistors T2, T3, T4, and T5. An area in which the first well areas W11, W12, and W13 overlap the first gate electrodes GE11, GE12, and GE13 in a plan view may be greater than an area in which the second, third, fourth, and fifth well areas W21, W22, W23, W31, W32, W33, W41, W42, W43, W51, W52, and W53 overlap the second, third, fourth, and fifth gate electrodes GE2, GE3, GE4, and GE5 in a plan view, respectively. For example, a length L of the first gate electrode GE11, GE12, and GE13 between the first source area SA11, SA12, and DA13 and the first drain area DA11, DA12, and DA13 of the first transistor T1 may be relatively longer than lengths of second, third, fourth, and fifth gate electrodes GE2, GE3, GE4, and GE5 between the second, third, fourth, and fifth source areas SA21, SA22, SA23, SA31, SA32, SA33, SA41, SA42, SA43, SA51, SA52, and SA53 and the second, third, fourth, and fifth drain areas DA21, DA22, DA23, DA31, DA32, DA33, DA41, DA42, DA43, DA51, DA52, and DA53, respectively. For example, the length L may be about 0.5 micrometers (μm) to about 5 μm, but the present disclosure is not limited thereto.

In one or more embodiments, because at least one of the transistors included in each of the plurality of sub-pixels is arranged to share the gate electrode, a space within the sub-pixel areas may be sufficiently secured. For example, because the second, third, fourth, and fifth transistors T2, T3, T4, and T5 share the second, third, fourth, and fifth gate electrodes GE2, GE3, GE4, and GE5, respectively, a space within the first, second, and third sub-pixel areas SPXA1, SPXA2, and SPXA3 may be sufficiently secured. That is, a relatively large number of transistors may be arranged within a limited area of the pixel area PXA.

Accordingly, a sufficient spare (or margin) area other than an area occupied by the second, third, fourth, and fifth transistors T2, T3, T4, and T5 may be secured in the pixel area PXA, and the first transistor T1 having a relatively large size (e.g., having a relatively long length L) may be arranged in the spare area. That is, the size of the first transistor T1 may be sufficiently secured. The body pattern BP may also be arranged in the spare area. For example, the first power voltage ELVDD may be provided to the body pattern BP.

Although FIG. 5 illustrates that 15 transistors (e.g., the first, second, third, fourth, and fifth transistors T1, T2, T3, T4, and T5 of each of the first, second, and third sub-pixels SPX1, SPX2, and SPX3) are arranged in the pixel area PXA, the present disclosure is not limited thereto. Because the space is sufficiently secured within the first, second, and third sub-pixel areas SPXA1, SPXA2, and SPXA3, a relatively larger number of transistors may be arranged in the pixel area PXA.

In one or more embodiments of the present disclosure, the display device DD may include the pixels PX each including a plurality of sub-pixels SPX1, SPX2, and SPX3. At least one of the transistors T1, T2, T3, T4, and T5 included in each of the sub-pixels SPX1, SPX2, and SPX3 may be arranged together while sharing a gate electrode. Accordingly, because a space within the pixel area PXA may be sufficiently secured, a plurality of transistors may be arranged in the pixel area PXA, and a size of a driving transistor may be sufficiently secured. Accordingly, the display device DD may be implemented with high resolution, and display quality of the display device DD may be improved.

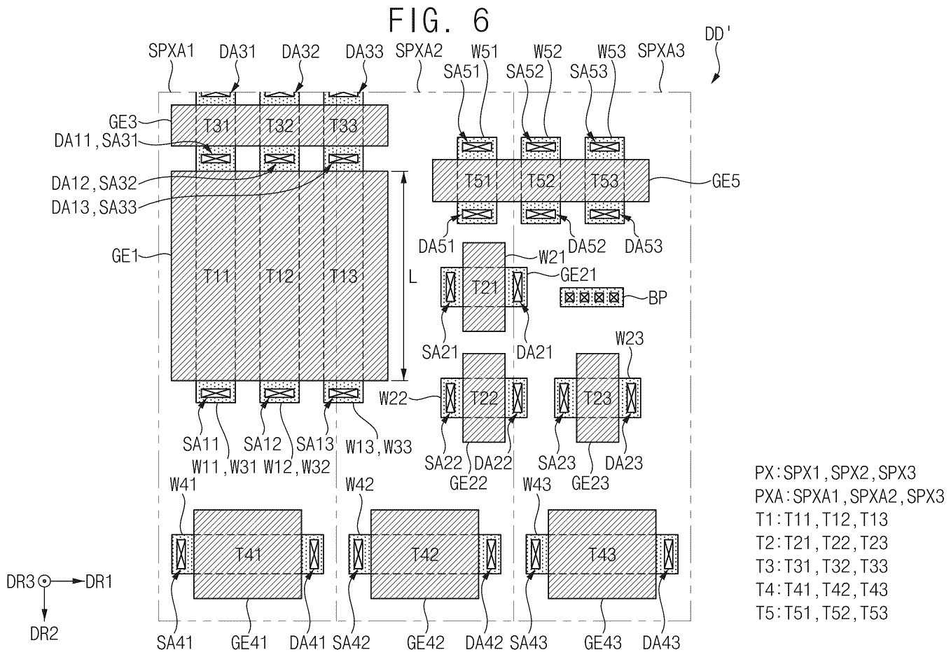

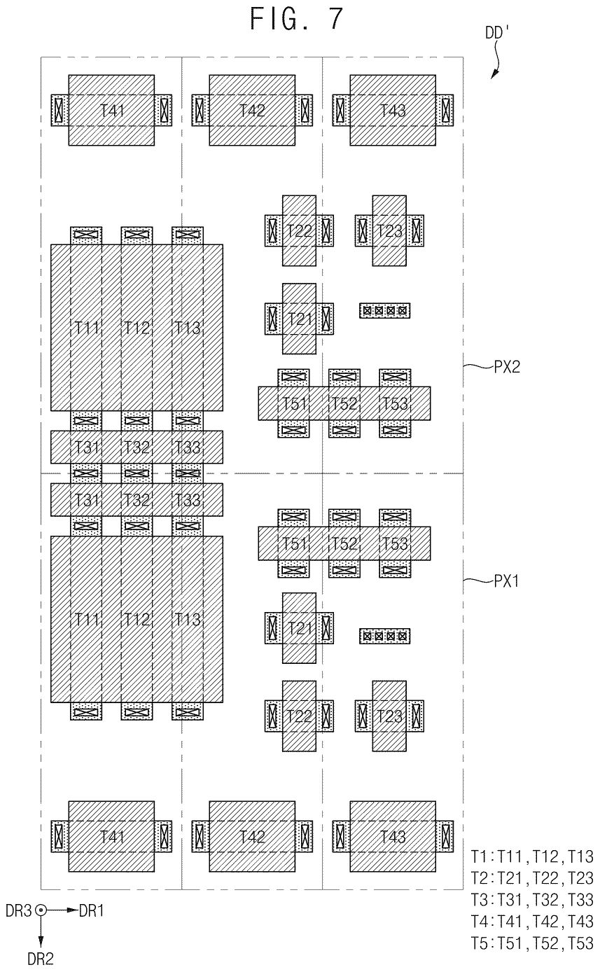

FIG. 6 is a plan view illustrating a display device according to one or more embodiments of the present disclosure. FIG. 7 is a plan view illustrating the display device of FIG. 6.

A display device DD′ described with reference to FIGS. 6 and 7 may be substantially similar to or identical to the display device DD described with reference to FIGS. 1, 2, 3, 4, and 5 except for the arrangement of transistors. Hereinafter, redundant descriptions will be omitted or simplified.

FIG. 6 may be a plan view corresponding to the plan view of FIG. 5. That is, FIG. 6 may be a plan view illustrating an example of a pixel PX included in the display device DD′. FIG. 7 may be a plan view illustrating two pixels PX adjacent to each other (e.g., adjacent vertically).

Referring to FIGS. 6 and 7, the pixel PX may include first, second, and third sub-pixels SPX1, SPX2, and SPX3 and a body pattern BP.

An area in which the first sub-pixel SPX1 emits light may be defined as a first sub-pixel area SPXA1, an area in which the second sub-pixel SPX2 emits light may be defined as a second sub-pixel area SPXA2, and an area in which the third sub-pixel SPX3 emits light may be defined as a third sub-pixel area SPXA3. The first, second, and third sub-pixel areas SPXA1, SPXA2, and SPXA3 may be adjacent to each other. For example, the first, second, and third sub-pixel areas SPXA1, SPXA2, and SPXA3 may be arranged in the first direction DR1, but the present disclosure is not limited thereto.

The first, second, and third sub-pixel areas SPXA1, SPXA2, and SPXA3 may be areas that emit light of different respective wavelength bands. For example, the first sub-pixel area SPXA1 may be an area that emits light of a red wavelength band, the second sub-pixel area SPXA2 may be an area that emits light of a green wavelength band, and the third sub-pixel area SPXA3 may be an area that emits light of a blue wavelength band, but the present disclosure is not limited thereto.

The first, second, and third sub-pixel areas SPXA1, SPXA2, and SPXA3 may define a pixel area PXA. The pixel area PXA may be defined as an area in which the pixel PX emits light. The pixel area PXA may be repeatedly arranged in the first direction DR1 and the second direction DR2 in a display area of the display device DD′. A unit repeating along the first direction DR1 and the second direction DR2 may be defined as the pixel area PXA.

The first sub-pixel SPX1 may include a first first transistor T11 (e.g., a first driving transistor in the claims, hereinafter, will be referred to as “(1-1)th transistor”), a first second transistor T21 (e.g., a fourth switching transistor in the claims, hereinafter, will be referred to as “(2-1)th transistor”), a first third transistor T31 (e.g., a first switching transistor in the claims, hereinafter, will be referred to as “(3-1)th transistor”), a first fourth transistor T41 (e.g., a fourth switching transistor in the claims, hereinafter, will be referred to as “(4-1)th transistor”), and a first fifth transistor T51 (hereinafter, will be referred to as “(5-1)th transistor”). The second sub-pixel SPX2 may include a second first transistor T12 (e.g., a second driving transistor in the claims, hereinafter, will be referred to as “(1-2)th transistor”), a second second transistor T22 (e.g., a fifth switching transistor in the claims, hereinafter, will be referred to as “(2-2)th transistor”), a second third transistor T32 (e.g., a second switching transistor in the claims, hereinafter, will be referred to as “(3-2)th transistor”), a second fourth transistor T42 (e.g., a fifth switching transistor in the claims, hereinafter, will be referred to as “(4-2)th transistor”), and a second fifth transistor T52 (hereinafter, will be referred to as “(5-2)th transistor”). The third sub-pixel SPX3 may include a third first transistor T13 (e.g., a third driving transistor in the claims, hereinafter, will be referred to as “(1-3)th transistor”), a third second transistor T23 (e.g., a sixth switching transistor in the claims, hereinafter, will be referred to as “(2-3)th transistor”), a third third transistor T33 (e.g., a third switching transistor in the claims, hereinafter, will be referred to as “(3-3)th transistor”), a third fourth transistor T43 (e.g., a sixth switching transistor in the claims, hereinafter, will be referred to as “(4-3)th transistor”), and a third fifth transistor T53 (hereinafter, will be referred to as “(5-3)th transistor”).

Each of the (1-1)th, (1-2)th, and (1-3)th transistors T11, T12, and T13 may correspond to a first transistor T1. Each of the (2-1)th, (2-2)th, and (2-3)th transistors T21, T22, and T23 may correspond to a second transistor T2. Each of the (3-1)th, (3-2)th, and (3-3)th transistors T31, T32, and T33 may correspond to a third transistor T3. Each of the (4-1)th, (4-2)th, and (4-3)th transistors T41, T42, and T43 may correspond to a fourth transistor T4. Each of the (5-1)th, (5-2)th, and (5-3)th transistors T51, T52, and T53 may correspond to a fifth transistor T5.

At least a portion of the (1-1)th, (2-1)th, (3-1)th, (4-1)th, and (5-1)th transistors T11, T21, T31, T41, and T51 of the first sub-pixel SPX1 might not be arranged in the first sub-pixel area SPXA1, and may be arranged in the second sub-pixel area SPXA2 and/or the third sub-pixel area SPXA3. For example, referring to FIG. 6, the (1-1)th, (3-1)th, and (4-1)th transistors T11, T31, and T41 may be arranged in the first sub-pixel area SPXA1, and the (2-1)th and (5-1)th transistors T21 and T51 may be arranged in the second sub-pixel area SPXA2, but the present disclosure is not limited thereto. That is, the first sub-pixel area SPXA1 might not be defined as an area in which the (1-1)th, (2-1)th, (3-1)th, (4-1)th, and (5-1)th transistors T11, T21, T31, T41, and T51 are arranged.

At least a portion of the (1-2)th, (2-2)th, (3-2)th, (4-2)th, and (5-2)th transistors T12, T22, T32, T42, and T52 of the second sub-pixel SPX2 might not be arranged in the second sub-pixel area SPXA2, and may be arranged in the first sub-pixel area SPXA1 and/or the third sub-pixel area SPXA3. For example, referring to FIG. 6, the (1-2)th and (3-2)th transistors T12 and T32 may be arranged in the first sub-pixel area SPXA1, the (2-2)th and (4-2)th transistors T22 and T42 may be arranged in the second sub-pixel area SPXA2, and the (5-2)th transistor T52 may be arranged in the third sub-pixel area SPXA3, but the present disclosure is not limited thereto. That is, the second sub-pixel area SPXA2 might not be defined as an area in which the (1-2)th, (2-2)th, (3-2)th, (4-2)th, and (5-2)th transistors T12, T22, T32, T42, and T52 are arranged.

At least a portion of the (1-3)th, (2-3)th, (3-3)th, (4-3)th, and (5-3)th transistors T13, T23, T33, T43, and T53 of the third sub-pixel SPX3 might not be arranged in the third sub-pixel area SPXA3, and may be arranged in the first sub-pixel area SPXA1 and/or the second sub-pixel area SPXA2. For example, referring to FIG. 6, the (1-3)th and (3-3)th transistors T13 and T33 may be arranged in the first and second sub-pixel areas SPXA1 and SPXA2, and the (2-3)th, (4-3)th, and (5-3)th transistors T23, T43, and T53 may be arranged in the third sub-pixel area SPXA3, but the present disclosure is not limited thereto. That is, the third sub-pixel area SPXA3 might not be defined as an area in which the (1-3)th, (2-3)th, (3-3)th, (4-3)th, and (5-3)th transistors T13, T23, T33, T43, and T53 are arranged.

A first first well area W11 (e.g., a first well area in the claims, hereinafter, will be referred to as “(1-1)th well area”) and a first gate electrode GE1 (e.g., a first gate electrode, a third gate electrode, and/or a fifth gate electrode in the claims) may define the (1-1)th transistor T11. The (1-1)th well area W11 and the first gate electrode GE1 may at least partially overlap in a plan view. The (1-1)th well area W11 may include a first first source area SA11 (e.g., a first source area in the claims, hereinafter, will be referred to as “(1-1)th source area”) and a first first drain area DA11 (e.g., a first drain area in the claims, hereinafter, will be referred to as “(1-1)th drain area”). For example, the first gate electrode GE1 may be arranged between the (1-1)th source area SA11 and the (1-1)th drain area DA11 in a plan view.

A second first well area W12 (e.g., a third well area in the claims, hereinafter, will be referred to as “(1-2)th well area”) and the first gate electrode GE1 may define the (1-2)th transistor T12. The (1-2)th well area W12 and the first gate electrode GE1 may at least partially overlap in a plan view. The (1-2)th well area W12 may include a second first source area SA12 (hereinafter, will be referred to as “(1-2)th source area”) and a second first drain area DA12 (hereinafter, will be referred to as “(1-2)th drain area”). For example, the first gate electrode GE1 may be arranged between the (1-2)th source area SA12 and the (1-2)th drain area DA12 in a plan view.

A third first well area W13 (e.g., a fifth well area in the claims, hereinafter, will be referred to as “(1-3)th well area”) and the first gate electrode GE1 may define the (1-3)th transistor T13. The (1-3)th well area W13 and the first gate electrode GE1 may at least partially overlap in a plan view. The (1-3)th well area W13 may include a third first source area SA13 (hereinafter, will be referred to as “(1-3)th source area”) and a third first drain area DA13 (hereinafter, will be referred to as “(1-3)th drain area”). For example, the first gate electrode GE1 may be arranged between the (1-3)th source area SA13 and the (1-3)th drain area DA13 in a plan view.

In one or more embodiments, the (1-1)th, (1-2)th, and (1-3)th transistors T11, T12, and T13 may share the first gate electrode GE1. That is, gate electrodes of the (1-1)th, (1-2)th, and (1-3)th transistors T11, T12, and T13 may be integral. One first gate electrode GE1 may extend to at least partially overlap each of the (1-1)th, (1-2)th, and (1-3)th well areas W11, W12, and W13 in a plan view. Accordingly, the first transistors T1 of the first, second, and third sub-pixels SPX1, SPX2, and SPX3 may be arranged adjacent to each other. As the first transistors T1 of the first, second, and third sub-pixels SPX1, SPX2, and SPX3 are arranged together, an area occupied by the first transistors T1 in the first, second, and third sub-pixel areas SPXA1, SPX2, and SPXA3 may be reduced.

A first second well area W21 (e.g., a seventh well area in the claims, hereinafter, will be referred to as “(2-1)th well area”) and a first second gate electrode GE21 (e.g., a seventh gate electrode in the claims, hereinafter, will be referred to as “(2-1)th gate electrode”) may define the (2-1)th transistor T21. The (2-1)th well area W21 and the (2-1)th gate electrode GE21 may at least partially overlap in a plan view. The (2-1)th well area W21 may include a first second source area SA21 (hereinafter, will be referred to as “(2-1)th source area”) and a first second drain area DA21 (hereinafter, will be referred to as “(2-1)th drain area”). For example, the (2-1)th gate electrode GE21 may be arranged between the (2-1)th source area SA21 and the (2-1)th drain area DA21 in a plan view.

A second second well area W22 (e.g., an eighth well area in the claims, hereinafter, will be referred to as “(2-2)th well area”) and a second second gate electrode GE22 (e.g., an eighth gate electrode in the claims, hereinafter, will be referred to as “(2-2)th gate electrode”) may define the (2-2)th transistor T22. The (2-2)th well area W22 and the (2-2)th gate electrode GE22 may at least partially overlap in a plan view. The (2-2)th well area W22 may include a second second source area SA22 (hereinafter, will be referred to as “(2-2)th source area”) and a second second drain area DA22 (hereinafter, will be referred to as “(2-2)th drain area”). For example, the (2-2)th gate electrode GE22 may be arranged between the (2-2)th source area SA22 and the (2-2)th drain area DA22 in a plan view.

A third second well area W23 (e.g., a ninth well area in the claims, hereinafter, will be referred to as “(2-3)th well area”) and a third second gate electrode GE23 (e.g., a ninth gate electrode in the claims, hereinafter, will be referred to as “(2-3)th gate electrode”) may define the (2-3)th transistor T23. The (2-3)th well area W23 and the (2-3)th gate electrode GE23 may at least partially overlap in a plan view. The (2-3)th well area W23 may include a third second source area SA23 (hereinafter, will be referred to as “(2-3)th source area”) and a third second drain area DA23 (hereinafter, will be referred to as “(2-3)th drain area”). For example, the (2-3)th gate electrode may be arranged between the (2-3)th source area SA23 and the (2-3)th drain area DA23 in a plan view.

In one or more embodiments, the (2-1)th, (2-2)th, and (2-3)th gate electrodes GE21, GE22, and GE23 may be spaced apart from each other.

A first third well area W31 (e.g., a second well area in the claims, hereinafter, will be referred to as “(3-1)th well area”) and a third gate electrode GE3 (e.g., a second gate electrode, a fourth gate electrode, and/or a sixth gate electrode in the claims) may define the (3-1)th transistor T31. The (3-1)th well area W31 and the third gate electrode GE3 may at least partially overlap in a plan view. The (3-1)th well area W31 may include a first third source area SA31 (e.g., a second source area in the claims, hereinafter, will be referred to as “(3-1)th source area”) and a first third drain area DA31 (e.g., a second drain area in the claims, hereinafter, will be referred to as “(3-1)th drain area”). For example, the third gate electrode GE3 may be arranged between the (3-1)th source area SA31 and the (3-1)th drain area DA31 in a plan view.

In one or more embodiments, the (3-1)th well area W31 may have a same configuration as the (1-1)th well area W11 (as used herein, “may have a same configuration as” may mean “may be integral with”). The (3-1)th well area W31 may extend from the (1-1)th well area W11. The (1-1)th and (3-1)th well areas W11 and W31 may be integral.

In one or more embodiments, the (3-1)th source area SA31 may have a same configuration as the (1-1)th drain area DA11. An area in which the (3-1)th well area W31 and a source electrode of the (3-1)th transistor T31 are connected (e.g., the (3-1)th source area S31) may be an area in which the (1-1)th well area W11 and a drain electrode of the (1-1)th transistor T11 are connected (e.g., the (1-1)th drain area). That is, the (1-1)th transistor T11 and the (3-1)th transistor T31 may share a well area (e.g., the (1-1)th well area W11 or the (3-1)th well area W31) and a connection area (e.g., the (1-1)th drain area DA11 or the (3-1)th source area SA31).

A second third well area W32 (e.g., a fourth well area in the claims, hereinafter, will be referred to as “(3-2)th well area”) and the third gate electrode GE3 may define the (3-2)th transistor T32. The (3-2)th well area W32 and the third gate electrode GE3 may at least partially overlap in a plan view. The (3-2)th well area W32 may include a second third source area SA32 (hereinafter, will be referred to as “(3-2)th source area”) and a second third drain area DA32 (hereinafter, will be referred to as “(3-2)th drain area”). For example, the third gate electrode GE3 may be arranged between the (3-2)th source area SA32 and the (3-2)th drain area DA32 in a plan view.

In one or more embodiments, the (3-2)th well area W32 may have a same configuration as the (1-2)th well area W12. The (3-2)th well area W32 may extend from the (1-2)th well area W12. The (1-2)th and (3-2)th well areas W12 and W32 may be integral.

In one or more embodiments, the (3-2)th source area SA32 may have a same configuration as the (1-2)th drain area DA12. An area in which the (3-2)th well area W32 and a source electrode of the (3-2)th transistor T32 are connected (e.g., the (3-2)th source area SA32) may be an area in which the (1-2)th well area W12 and a drain electrode of the (1-2)th transistor T12 are connected (e.g., the (1-2)th drain area DA12). That is, the (1-2)th transistor T12 and the (3-2)th transistor T32 may share a well area (e.g., the (1-2)th well area W12 or the (3-2)th well area W32) and a connection area (e.g., the (1-2)th drain area DA12 or the (3-2)th source area SA32).

A third third well area W33 (e.g., a sixth well area in the claims, hereinafter, will be referred to as “(3-3)th well area”) and the third gate electrode GE3 may define the (3-3)th transistor T33. The (3-3)th well area W33 and the third gate electrode GE3 may at least partially overlap in a plan view. The (3-3)th well area W33 may include a third third source area SA33 (hereinafter, will be referred to as “(3-3)th source area”) and a third third drain area DA33 (hereinafter, will be referred to as “(3-3)th drain area”). For example, the third gate electrode GE3 may be arranged between the (3-3)th source area SA33 and the (3-3)th drain area DA33 in a plan view.

In one or more embodiments, the (3-3)th well area W33 may have a same configuration as the (1-3)th well area W13. The (3-3)th well area W33 may extend from the (1-3)th well area W13. The (1-3)th and (3-3)th well areas W13 and W33 may be integral.

In one or more embodiments, the (3-3)th source area SA33 may have a same configuration as the (1-3)th drain area DA13. An area in which the (3-3)th well area W33 and a source electrode of the (3-3)th transistor T32 are connected (e.g., the (3-3)th source area SA33) may be an area in which the (1-3)th well area W13 and a drain electrode of the (1-3)th transistor T13 are connected (e.g., the (1-3)th drain area DA13). That is, the (1-3)th transistor T13 and the (3-3)th transistor T33 may share a well area (e.g., the (1-3)th well area W13 or the (3-3)th well area W33) and a connection area (e.g., the (1-3)th drain area DA13 or the (3-3)th source area SA33).

In one or more embodiments, the (3-1)th, (3-2)th, and (3-3)th transistors T31, T32, and T33 may share the third gate electrode GE3. That is, gate electrodes of the (3-1)th, (3-2)th, and (3-3)th transistors T31, T32, and T33 may be integral. One third gate electrode GE3 may extend to at least partially overlap each of the (3-1)th, (3-2)th and (3-3)th well areas W31, W32, and W33 in a plan view. Accordingly, the third transistors T3 of the first, second, and third sub-pixels SPX1, SPX2, and SPX3 may be arranged adjacent to each other. As the third transistors T3 of the first, second, and third sub-pixels SPX1, SPX2, and SPX3 are arranged together, an area occupied by the third transistors T3 in the first, second, and third sub-pixel areas SPXA1, SPXA2, and SPXA3 may be reduced.

In addition, in one or more embodiments, the (3-1)th transistor T31 may share the well area W11 and W31 with the (1-1)th transistor T11, the (3-2)th transistor T32 may share the well area W12 and W32 with the (1-2)th transistor T12, and the (3-3)th transistor T33 may share the well area W13 and W33 with the (1-3)th transistor T13. One well area may extend to at least partially overlap each of the first and third gate electrodes GE1 and GE3. Accordingly, the first transistors T1 and the third transistors T3 of the first, second, and third sub-pixels SPX1, SPX2 and SPX3 may be arranged adjacent to each other. As the first and third transistors T1 and T3 of the first, second, and third sub-pixels SPX1, SPX2, and SPX3 are arranged together, an area occupied by the first and third transistors T1 and T3 in the first, second, and third sub-pixel areas SPXA1, SPXA2, and SPXA3 may be reduced.

A first fourth well area W41 (e.g., a seventh well area in the claims, hereinafter, will be referred to as “(4-1)th well area”) and a first fourth gate electrode GE41 (e.g., a seventh gate electrode in the claims, hereinafter, will be referred to as “(4-1)th gate electrode”) may define the (4-1)th transistor T41. The (4-1)th well area W41 and the (4-1)th gate electrode GE41 may at least partially overlap in a plan view. The (4-1)th well area W41 may include a first fourth source area SA41 (hereinafter, will be referred to as “(4-1)th source area”) and a first fourth drain area DA41 (hereinafter, will be referred to as “(4-1)th drain area”). For example, the (4-1)th gate electrode GE41 may be arranged between the (4-1)th source area SA41 and the (4-1)th drain area DA41 in a plan view.

A second fourth well area W42 (e.g., an eighth well area in the claims, hereinafter, will be referred to as “(4-2)th well area”) and a second fourth gate electrode GE42 (e.g., an eighth gate electrode in the claims, hereinafter, will be referred to as “(4-2)th gate electrode”) may define the (4-2)th transistor T42. The (4-2)th well area W42 and the (4-2)th gate electrode GE42 may at least partially overlap in a plan view. The (4-2)th well area W42 may include a second fourth source area SA42 (hereinafter, will be referred to as “(4-2)th source area”) and a second fourth drain area DA42 (hereinafter, will be referred to as “(4-2)th drain area”). For example, the (4-2)th gate electrode GE42 may be arranged between the (4-2)th source area SA42 and the (4-2)th drain area DA42 in a plan view.

A third fourth well area W43 (e.g., a ninth well area in the claims, hereinafter, will be referred to as “(4-3)th well area”) and a third fourth gate electrode GE43 (e.g., a ninth gate electrode in the claims, hereinafter, will be referred to as “(4-3)th gate electrode”) may define the (4-3)th transistor T43. The (4-3)th well area W43 and the (4-3)th gate electrode GE43 may at least partially overlap in a plan view. The (4-3)th well area W43 may include a third fourth source area SA43 (hereinafter, will be referred to as “(4-3)th source area”) and a third fourth drain area DA43 (hereinafter, will be referred to as “(4-3)th drain area”). For example, the (4-3)th gate electrode GE43 may be arranged between the (4-3)th source area SA43 and the (4-3)th drain area DA43 in a plan view.

In one or more embodiments, the (4-1)th, (4-2)th, and (4-3)th gate electrodes GE41, GE42, and GE43 may be spaced apart from each other.

A first fifth well area W51 (hereinafter, will be referred to as “(5-1)th well area”) and a fifth gate electrode GE5 may define the (5-1)th transistor T51. The (5-1)th well area W51 and the fifth gate electrode GE5 may at least partially overlap in a plan view. The (5-1)th well area W51 may include a first fifth source area SA51 (hereinafter, will be referred to as “(5-1)th source area”) and a first fifth drain area DA51 (hereinafter, will be referred to as “(5-1)th drain area”). For example, the fifth gate electrode GE5 may be arranged between the (5-1)th source area SA51 and the (5-1)th drain area DA51 in a plan view.

A second fifth well area W52 (hereinafter, will be referred to as “(5-2)th well area”) and the fifth gate electrode GE5 may define the (5-2)th transistor T52. The (5-2)th well area W52 and the fifth gate electrode GE5 may at least partially overlap in a plan view. The (5-2)th well area W52 may include a second fifth source area SA52 (hereinafter, will be referred to as “(5-2)th source area”) and a second fifth drain area DA52 (hereinafter, will be referred to as “(5-2)th drain area”). For example, the fifth gate electrode GE5 may be arranged between the (5-2)th source area SA52 and the (5-2)th drain area DA52 in a plan view.

A third fifth well area W53 (hereinafter, will be referred to as “(5-3)th well area”) and the fifth gate electrode GE5 may define the (5-3)th transistor T53. The (5-3)th well area W53 and the fifth gate electrode GE5 may at least partially overlap in a plan view. The (5-3)th well area W53 may include a third fifth source area SA53 (hereinafter, will be referred to as “(5-3)th source area”) and a third fifth drain area DA53 (hereinafter, will be referred to as “(5-3)th drain area”). For example, the fifth gate electrode GE5 may be arranged between the (5-3)th source area SA53 and the (5-3)th drain area DA53 in a plan view.

In one or more embodiments, the (5-1)th, (5-2)th, and (5-3)th transistors T51, T52, and T53 may share the fifth gate electrode GE5. That is, gate electrodes of the (5-1)th, (5-2)th, and (5-3)th transistors T51, T52, and T53 may be integral. One fifth gate electrode GE5 may extend to at least partially overlap each of the (5-1)th, (5-2)th, and (5-3)th well areas W51, W52, and W53 in a plan view. Accordingly, the fifth transistors T5 of the first, second, and third sub-pixels SPX1, SPX2, and SPX3 may be arranged adjacent to each other. As the fifth transistors T5 of the first, second, and third sub-pixels SPX1, SPX2, and SPX3 are arranged together, an area occupied by the fifth transistors T5 in the first, second, and third sub-pixel areas SPXA1, SPXA2, and SPXA3 may be reduced.

In one or more embodiments, a size of the first transistor T1 may be relatively greater than a size of each of the second, third, fourth, and fifth transistors T2, T3, T4, and T5. For example, a length L of the first gate electrode GE1 between the first source area SA11, SA12, and DA13 and the first drain area DA11, DA12, and DA13 of the first transistor T1 may be relatively longer than lengths of second, third, fourth, and fifth gate electrodes GE21, GE22, GE23, GE3, GE41, GE42, GE43, and GE5 between the second, third, fourth, and fifth source areas SA21, SA22, SA23, SA31, SA32, SA33, SA41, SA42, SA43, SA51, SA52, and SA53 and the second, third, fourth, and fifth drain areas DA21, DA22, DA23, DA31, DA32, DA33, DA41, DA42, DA43, DA51, DA52, and DA53, respectively.

In one or more embodiments, pixels PX adjacent to each other among the pixels PX may be mirror-symmetric in a plan view. For example, as illustrated in FIG. 7, the pixels PX may include a first pixel PX1 and a second pixel PX2 adjacent to each other in the second direction DR2. The first and second pixels PX may be mirror-symmetric with respect to a virtual line extending in the first direction DR1.

The first pixel PX1 and the second pixel PX2 may share some configurations. For example, in one or more embodiments, the first pixel PX1 and the second pixel PX2 may share at least one of the well areas.

For example, as illustrated in FIG. 7, the first pixel PX1 and the second pixel PX2 may share the (1-1)th, (1-2)th, and (1-3)th well areas W11, W12, and W13 (e.g., the (3-1)th, (3-2)th, and (3-3)th well areas W31, W32, and W33). The (1-1)th, (1-2)th, and (1-3)th well areas W11, W12, and W13 of the first pixel PX1 may extend to the second pixel PX2. The (1-1)th, (1-2)th, and (1-3)th well areas W11, W12, and W13 may extend in the second direction DR2, and may be arranged in the first pixel PX1 and the second pixel PX2. The (3-1)th, (3-2)th, and (3-3)th drain areas DA31, DA32, and DA33 may be defined together in the first pixel PX1 and the second pixel PX2. That is, the (3-1)th, (3-2)th, and (3-3)th drain areas DA31, DA32, and DA33 may be arranged on the virtual line.

Although FIG. 7 illustrates that the pixels PX adjacent to each other in the second direction DR2 have a symmetrical structure, the present disclosure is not limited thereto. For example, the pixels PX adjacent to each other in the first direction DR1 may have a symmetrical (e.g., mirror symmetrical) structure.

In one or more embodiments, because at least one of the transistors included in each of the plurality of sub-pixels shares the gate electrode, a space within the sub-pixel areas may be sufficiently secured. For example, because the first, third, and fifth transistors T1, T3, and T5 share the first, third, and fifth gate electrodes, a space within the first, second, and third sub-pixel areas SPXA1, SPXA2, and SPXA3 may be sufficiently secured.

In addition, in one or more embodiments, because at least one of the transistors included in each of the plurality of sub-pixels shares the well area, a space within the sub-pixel areas may be sufficiently secured. For example, because the first and third transistors T1 and T3 share the first and third well areas, a space within the first, second, and third sub-pixel areas SPXA1, SPXA2, and SPXA3 may be more sufficiently secured. That is, a relatively large number of transistors may be arranged within a limited area of the pixel area PXA.

Accordingly, a sufficient spare (or margin) area other than an area occupied by the second, third, fourth, and fifth transistors T2, T3, T4, and T5 may be secured in the pixel area PXA, and the first transistor T1 having a relatively large size (e.g., having a relatively long length L) may be arranged in the spare area. That is, the size of the first transistor T1 may be sufficiently secured. The body pattern BP may also be arranged in the spare area. For example, the first power voltage ELVDD may be provided to the body pattern BP.

In one or more embodiments, at least one of the transistors included in each of the plurality of sub-pixels may be an NMOS transistor. In this case, a well area of the NMOS transistor may suitably be relatively further apart from other well areas. For example, the fourth transistor T4 may be an NMOS transistor. Because a space within the first, second, and third sub-pixel areas SPXA1, SPXA2, and SPXA3 is sufficiently secured, the fourth well areas W41, W42, and W43 of the fourth transistors T4 may be relatively further apart from other well areas.

In one or more embodiments of the present disclosure, the display device DD′ may include the pixels PX each including a plurality of sub-pixels SPX1, SPX2, and SPX3. At least one of the transistors T1, T2, T3, T4, and T5 included in each of the sub-pixels SPX1, SPX2, and SPX3 may be arranged together while sharing a gate electrode or a well area. Accordingly, because a space within the pixel area PXA may be sufficiently secured, a plurality of transistors may be arranged in the pixel area PXA, and a size of a driving transistor may be sufficiently secured. Accordingly, the display device DD′ may be implemented with high resolution, and display quality of the display device DD′ may be improved.

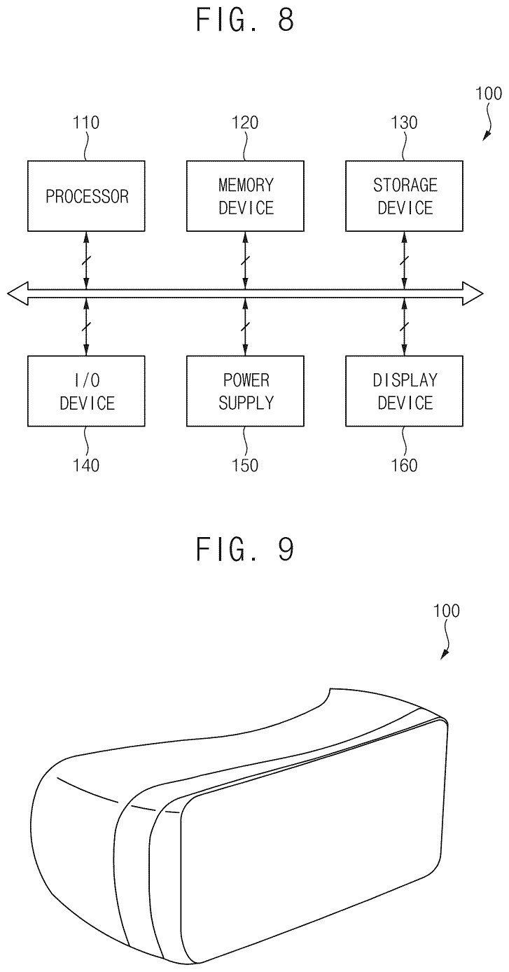

FIG. 8 is a block diagram illustrating an electronic device according to one or more embodiments of the present disclosure. FIG. 9 is a diagram illustrating an example in which the electronic device of FIG. 8 is implemented as a VR device.

Referring to FIGS. 8 and 9, an electronic device 100 may include a processor 110, a memory device 120, a storage device 130, an input/output (I/O) device 140, a power supply 150, and a display device 160. The display device 160 may be the above-described display device DD or DD′. The electronic device 100 may further include a plurality of ports for communicating with a video card, a sound card, a memory card, a universal serial bus (USB) device, other systems, or the like.

In one or more embodiments, as illustrated in FIG. 9, the electronic device 100 may be implemented as a VR device. However, this is exemplary, and the electronic device 100 is not limited thereto. For example, the electronic device 100 may be implemented as a cellular phone, a video phone, a television, a smart pad, a smart watch, a tablet PC, a vehicle display, a computer monitor, a laptop, a head-mounted display (HMD), or the like.

The processor 110 may perform various computing functions. The processor may control the display device 160. The processor 110 may be a microprocessor, a central processing unit (CPU), an application processor (AP), or the like. The processor 110 may be coupled to other components through an address bus, a control bus, a data bus, or the like. In one or more embodiments, the processor 110 may be coupled to an extended bus, such as a peripheral component interconnection (PCI) bus.

The memory device 120 may store data for operations of the electronic device 100. For example, the memory device 120 may include at least one non-volatile memory device, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device, such as a dynamic random access memory (DRAM) device, a static random access memory (SRAM) device, a mobile DRAM device, or the like.

The storage device 130 may include a solid-state drive (SSD) device, a hard disk drive (HDD) device, a CD-ROM device, or the like. The I/O device 140 may include an input device, such as a keyboard, a keypad, a mouse device, a touch-pad, a touch-screen, or the like, and an output device, such as a printer, a speaker, or the like.

The power supply 150 may provide power for operations of the electronic device 100. The display device 160 may be connected to other components through buses or other communication links. In one or more embodiments, the display device 160 may be included in the I/O device 140.

The present disclosure can be applied to various display devices and electronic devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims, with functional equivalents thereof to be included therein.

What is claimed is:

1. A display device comprising:
pixels comprising a first sub-pixel, a second sub-pixel, and a third sub-pixel adjacent to each other, wherein:
the first sub-pixel comprises:
a first driving transistor comprising a first well area, and a first gate electrode above the first well area; and
a first switching transistor comprising a second well area, and a second gate electrode above the second well area;
the second sub-pixel comprises:
a second driving transistor comprising a third well area, and a third gate electrode above the third well area; and
a second switching transistor comprising a fourth well area, and a fourth gate electrode above the fourth well area and connected to the second gate electrode; and
the third sub-pixel comprises:
a third driving transistor comprising a fifth well area, and a fifth gate electrode above the fifth well area; and
a third switching transistor comprising a sixth well area, and a sixth gate electrode above the sixth well area and connected to the second gate electrode.

2. The display device of claim 1, wherein the second gate electrode, the fourth gate electrode, and the sixth gate electrode are integral.

3. The display device of claim 1, wherein sizes of the first driving transistor, the second driving transistor, and the third driving transistor are larger than sizes of the first switching transistor, the second switching transistor, and the third switching transistor.

4. The display device of claim 1, wherein:
the first sub-pixel defines a first sub-pixel area for emitting first light;
the second sub-pixel defines a second sub-pixel area for emitting second light; and
the third sub-pixel defines a third sub-pixel area for emitting third light.

5. The display device of claim 4, wherein:
at least a portion of the first driving transistor and the first switching transistor is arranged in the second sub-pixel area or the third sub-pixel area;
at least a portion of the second driving transistor and the second switching transistor is arranged in the first sub-pixel area or the third sub-pixel area; and
at least a portion of the third driving transistor and the third switching transistor is arranged in the first sub-pixel area or the second sub-pixel area.

6. The display device of claim 1, wherein the first gate electrode, the third gate electrode, and the fifth gate electrode are spaced apart from each other.

7. The display device of claim 1, wherein the first gate electrode, the third gate electrode, and the fifth gate electrode are integral.

8. The display device of claim 1, wherein:
the first well area and the second well area are integral;
the third well area and the fourth well area are integral; and
the fifth well area and the sixth well area are integral.

9. The display device of claim 8, wherein:
the first well area comprises a first source area and a first drain area;
the second well area comprises a second source area and a second drain area; and
the first drain area is the second source area.

10. The display device of claim 1, wherein adjacent ones of the pixels are mirror-symmetrical.

11. The display device of claim 1, wherein:
the first sub-pixel further comprises a fourth switching transistor comprising a seventh well area, and a seventh gate electrode above the seventh well area;
the second sub-pixel further comprises a fifth switching transistor comprising an eighth well area, and an eighth gate electrode above the eighth well area; and
the third sub-pixel further comprises a sixth switching transistor comprising a ninth well area, and a ninth gate electrode above the ninth well area.

12. The display device of claim 11, wherein the seventh gate electrode, the eighth gate electrode, and the ninth gate electrode are spaced apart from each other.

13. The display device of claim 1, wherein:
the first well area and the first gate electrode at least partially overlap in plan view;
the second well area and the second gate electrode at least partially overlap in plan view;
the third well area and the third gate electrode at least partially overlap in plan view;
the fourth well area and the fourth gate electrode at least partially overlap in plan view;
the fifth well area and the fifth gate electrode at least partially overlap in plan view; and
the sixth well area and the sixth gate electrode at least partially overlap in plan view.

14. The display device of claim 4, wherein the first light, the second light, and the third light are respectively of different wavelength bands.

15. The display device of claim 14, wherein:
the first light is light of a red wavelength band;
the second light is light of a green wavelength band; and
the third light is light of a blue wavelength band.

16. An electronic device comprising:
a display device; and
a processor for controlling the display device,
wherein the display device comprises pixels comprising a first sub-pixel, a second sub-pixel, and a third sub-pixel adjacent to each other,
wherein the first sub-pixel comprises:
a first driving transistor comprising a first well area, and a first gate electrode above the first well area; and
a first switching transistor comprising a second well area, and a second gate electrode above the second well area,
wherein the second sub-pixel comprises:
a second driving transistor comprising a third well area, and a third gate electrode above the third well area; and
a second switching transistor comprising a fourth well area, and a fourth gate electrode above the fourth well area and connected to the second gate electrode, and
wherein the third sub-pixel comprises:
a third driving transistor comprising a fifth well area, and a fifth gate electrode above the fifth well area; and
a third switching transistor comprising a sixth well area, and a sixth gate electrode above the sixth well area and connected to the second gate electrode.

17. The electronic device of claim 16, wherein the second gate electrode, the fourth gate electrode, and the sixth gate electrode are integral.

18. The electronic device of claim 16, wherein:
the first sub-pixel defines a first sub-pixel area for emitting first light;
the second sub-pixel defines a second sub-pixel area for emitting second light;
the third sub-pixel defines a third sub-pixel area for emitting third light;
at least a portion of the first driving transistor and the first switching transistor is arranged in the second sub-pixel area or the third sub-pixel area;
at least a portion of the second driving transistor and the second switching transistor is arranged in the first sub-pixel area or the third sub-pixel area; and
at least a portion of the third driving transistor and the third switching transistor is arranged in the first sub-pixel area or the second sub-pixel area.

19. The electronic device of claim 16, wherein the first gate electrode, the third gate electrode, and the fifth gate electrode are integral.

20. The electronic device of claim 16, wherein:
the first well area and the second well area are integral;
the third well area and the fourth well area are integral; and
the fifth well area and the sixth well area are integral.
